(19) United States
(12) Patent Application Publication
(10) Pub. No.: US 2024/0373632 A1
(43) Pub. Date: Nov. 7, 2024

(54) THREE-DIMENSIONAL SEMICONDUCTOR MEMORY DEVICE, AN ELECTRONIC SYSTEM INCLUDING THE SAME, AND METHOD OF FABRICATING THE SAME

(71) Applicant: SAMSUNG ELECTRONICS CO., LTD., Suwon-si (KR)

(72) Inventors: Kang Lib Kim, Suwon-si (KR); Sungsu Moon, Suwon-si (KR); Sea Hoon Lee, Suwon-si (KR); Junhee Lim, Suwon-si (KR)

(21) Appl. No.: 18/406,913

(22) Filed: Jan. 8, 2024

(30) Foreign Application Priority Data
May 4, 2023 (KR) 10-2023-0058692

(51) Int. Cl. H10B 43/27; H01L 23/522; H10B 43/40

(52) U.S. Cl. CPC H10B 43/27; H01L 23/5223; H01L 23/5228; H10B 43/40

(57) ABSTRACT

Disclosed are 3D semiconductor memory devices and electronic systems including the same. The 3D semiconductor memory device comprises a first substrate including a cell array region and a contact region, a stack structure including interlayers and gate electrodes and including a pad part having a stepwise structure on the contact region, a first dielectric layer covering the pad part of the stack structure, a second dielectric layer on the first dielectric layer, an interlayer capacitor between the first dielectric layer and the second dielectric layer, cell contact plugs penetrating the pad part of the stack structure, the first dielectric layer, and the second dielectric layer and correspondingly connected to the gate electrodes, and lower and upper conductive lines penetrating the pad part of the stack structure, the first dielectric layer, and the second dielectric layer and electrically connected to the interlayer capacitor.

### CROSS-REFERENCE TO RELATED APPLICATION

This U.S. nonprovisional application claims priority under 35 U.S.C. § 119 to Korean Patent Application No. 10-2023-0058692 filed on May 4, 2023, in the Korean Intellectual Property Office, the disclosure of which is hereby incorporated by reference in its entirety.

### BACKGROUND

It is desirable to have a semiconductor device capable of storing a large amount of data in an electronic system which requires data storage. A semiconductor device has been highly integrated to meet high performance and low manufacturing cost which are required by customers. Integration of typical two-dimensional or planar semiconductor devices is primarily determined by the area occupied by a unit memory cell, such that it is greatly influenced by the level of technology for forming fine patterns. However, the extremely expensive processing equipment needed to increase pattern fineness may set a practical limitation on increasing the integration of the two-dimensional or planar semiconductor devices.

### SUMMARY

The present inventive concepts relate to a three-dimensional semiconductor memory device, an electronic system including the same, and a method of fabricating the same, and more particularly, to a three-dimensional semiconductor memory device including a peripheral circuit structure and a cell array structure that are bonded through bonding pads, an electronic system including the same, and a method of fabricating the same.

Some implementations of the present inventive concepts provide a structure capable of reducing a size of a three-dimensional semiconductor memory device.

Some implementations of the present inventive concepts provide an electronic system including the three-dimensional semiconductor memory device.

The features and advantages of the present inventive concepts is not limited to those mentioned above, and other features and advantages which have not been mentioned above will be clearly understood to those skilled in the art from the following description.

According to some implementations of the present inventive concepts, a three-dimensional semiconductor memory device may comprise: a first substrate that includes a cell array region and a contact region extending from the cell array region; a stack structure that includes interlayers and gate electrodes alternately stacked on the first substrate, wherein the stack structure includes a pad part having a stepwise structure on the contact region; a first dielectric layer that covers the pad part of the stack structure; a second dielectric layer on the first dielectric layer; an interlayer capacitor between the first dielectric layer and the second dielectric layer; a plurality of cell contact plugs that penetrate the pad part of the stack structure, the first dielectric layer, and the second dielectric layer and are correspondingly connected to the gate electrodes; and a lower conductive line and an upper conductive line that penetrate the pad part of the stack structure, the first dielectric layer, and the second dielectric layer and are electrically connected to the interlayer capacitor.

According to some implementations of the present inventive concepts, a three-dimensional semiconductor memory device may comprise: a first substrate that includes a cell array region and a contact region extending from the cell array region; a stack structure that includes interlayers and gate electrodes alternately stacked on the first substrate, wherein the stack structure includes a pad part having a stepwise structure on the contact region; a first dielectric layer that covers the pad part of the stack structure; an interlayer resistive plate on the first dielectric layer; a second dielectric layer that covers the first dielectric layer and the interlayer resistive plate; a plurality of cell contact plugs that penetrate the pad part of the stack structure, the first dielectric layer, and the second dielectric layer and are correspondingly connected to the gate electrodes; and a resistance conductive line that penetrates the pad part of the stack structure, the first dielectric layer, the interlayer resistive plate, and the second dielectric layer and is connected to the interlayer resistive plate.

According to some implementations of the present inventive concepts, a three-dimensional semiconductor memory device may comprise: a first substrate that includes a cell array region and a contact region extending from the cell array region; a stack structure that includes interlayers and gate electrodes alternately stacked on the first substrate, wherein the stack structure includes a pad part having a stepwise structure on the contact region; a first dielectric layer that covers the pad part of the stack structure; a lower electrode plate on the first dielectric layer; a first interlayer dielectric layer that covers the first dielectric layer and the lower electrode plate; an upper electrode plate on the first interlayer dielectric layer; a second dielectric layer that covers the first interlayer dielectric layer and the upper electrode plate; an interlayer resistive plate on the second dielectric layer; an upper dielectric layer that covers the second dielectric layer and the interlayer resistive plate; a plurality of cell contact plugs that penetrate the pad part of the stack structure, the first dielectric layer, the first interlayer dielectric layer, the second dielectric layer, and the upper dielectric layer and are correspondingly connected to the gate electrodes; a lower conductive line that penetrates the pad part of the stack structure, the first dielectric layer, the first interlayer dielectric layer, the second dielectric layer, and the upper dielectric layer, and the lower electrode plate; an upper conductive line that penetrates the pad part of the stack structure, the first dielectric layer, the first interlayer dielectric layer, the second dielectric layer, and the upper dielectric layer, and the upper electrode plate; and a resistance conductive line that penetrates the pad part of the stack structure, the first dielectric layer, the first interlayer dielectric layer, the second dielectric layer, and the upper dielectric layer, and the interlayer resistive plate.

According to some implementations of the present inventive concepts, an electronic system may comprise: a first substrate that includes a cell array region and a contact region extending from the cell array region; a three-dimensional semiconductor memory device that includes a peripheral circuit structure on the first substrate, a cell array structure on the peripheral circuit structure, a upper layer that covers the cell array structure, and an input/output pad on the upper layer and electrically connected to the peripheral circuit structure; and a controller configured to electrically connect through the input/output pad with the three-dimensional semiconductor memory device and to control the three-dimensional semiconductor memory device. The cell array structure may include: a second substrate on the peripheral circuit structure; a stack structure that includes interlayers and gate electrodes alternately stacked on the second substrate, wherein the stack structure includes a pad part having a stepwise structure on the contact region; a first dielectric layer that covers the pad part of the stack structure; a second dielectric layer on the first dielectric layer; an interlayer capacitor between the first dielectric layer and the second dielectric layer; a plurality of cell contact plugs that penetrate the pad part of the stack structure, the first dielectric layer, and the second dielectric layer and are correspondingly connected to the gate electrodes; and a lower conductive line and an upper conductive line that penetrate the pad part of the stack structure, the first dielectric layer, and the second dielectric layer and is electrically connected to the interlayer capacitor.

### BRIEF DESCRIPTION OF THE DRAWINGS

FIG. 1 illustrates a simplified block diagram showing an electronic system that includes a three-dimensional semiconductor memory device according to some implementations of the present inventive concepts.

FIG. 2 illustrates a simplified perspective view showing an electronic system that includes a three-dimensional semiconductor memory device according to some implementations of the present inventive concepts.

FIGS. 3 and 4 illustrate cross-sectional views respectively taken along lines I-I′ and II-II′ of FIG. 2, showing a semiconductor package that includes a three-dimensional semiconductor memory device according to some implementations of the present inventive concepts.

FIG. 5 illustrates a plan view showing a three-dimensional semiconductor memory device according to some implementations of the present inventive concepts.

FIGS. 6A and 6B illustrate cross-sectional views respectively taken along lines I-I′ and II-II′ of FIG. 5, showing a three-dimensional semiconductor memory device according to some implementations of the present inventive concepts.

FIG. 7A illustrates an enlarged view of section A depicted in FIG. 6A, partially showing a three-dimensional semiconductor memory device according to some implementations of the present inventive concepts.

FIG. 7B illustrates an enlarged view of section B depicted in FIG. 6A, partially showing a three-dimensional semiconductor memory device according to some implementations of the present inventive concepts.

FIGS. 8 to 10, 11A, 12, 13A, 14, 15A, and 16 to 19 illustrate cross-sectional views taken along line II-II′ of FIG. 5, showing a method of fabricating a three-dimensional semiconductor memory device according to some implementations of the present inventive concepts.

FIGS. 11B, 13B, and 15B illustrate plan views of FIGS. 11A, 13A, and 15A, respectively.

FIGS. 20A, 20B, 21 to 22, 23A, 23B, and 24 to 26 illustrate plan and cross-sectional views showing a three-dimensional semiconductor memory device according to some implementations of the present inventive concepts.

### DETAILED DESCRIPTION

In conjunction with the accompanying drawings, the following will describe in detail a three-dimensional semiconductor memory device, a method of fabricating the same, and an electronic system including the same according to some implementations of the present inventive concepts.

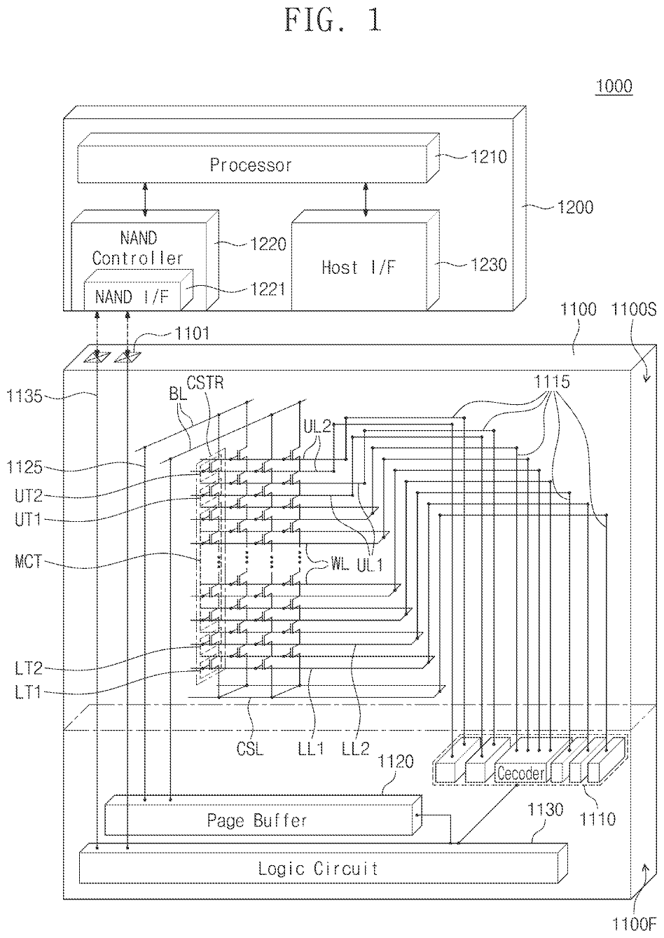

FIG. 1 illustrates a simplified block diagram showing an electronic system that includes a three-dimensional semiconductor memory device according to some implementations of the present inventive concepts.

Referring to FIG. 1, an electronic system 1000 according to some implementations of the present inventive concepts includes a three-dimensional semiconductor memory device 1100 and a controller 1200 electrically connected to the three-dimensional semiconductor memory device 1100. The electronic system 1000 may be a storage device that includes a single or a plurality of three-dimensional semiconductor memory devices 1100 or may be an electronic device that includes the storage device. For example, the electronic system 1000 may be a solid state drive (SSD) device, a universal serial bus (USB), a computing system, a medical apparatus, or a communication apparatus each of which includes a single or a plurality of three-dimensional semiconductor memory devices 1100.

The three-dimensional semiconductor memory device 1100 may be a nonvolatile memory device, such as a three-dimensional NAND Flash memory device which will be discussed below. The three-dimensional semiconductor memory device 1100 may include a first region 1100F and a second region 1100S on the first region 1100F. For example, the first region 1100F may be disposed on a side of the second region 1100S. The first region 1100F may be a peripheral circuit region that includes a decoder circuit 1110, a page buffer 1120, and a logic circuit 1130. The second region 1100S may be a memory cell region that includes bit lines BL, a common source line CSL, word lines WL, first lines LL1 and LL2, second lines UL1 and UL2, and memory cell strings CSTR between the bit line BL and the common source line CSL.

On the second region 1100S, each of the memory cell strings CSTR may include first transistors LT1 and LT2 adjacent to the common source line CSL, second transistors UT1 and UT2 adjacent to the bit line BL, and memory cell transistors MCT disposed between the first transistors LT1 and LT2 and the second transistors UT1 and UT2. The number of the first transistors LT1 and LT2 and of the second transistors UT1 and UT2 may be variously changed in accordance with implementations.

For example, the first transistors LT1 and LT2 may include a ground selection transistor, and the second transistors UT1 and UT2 may include a string selection transistor. The first lines LL1 and LL2 may be gate electrodes of the first transistors LT1 and LT2, respectively. The word lines WL may be gate electrodes of the memory cell transistors MCT. The second lines UL1 and UL2 may be gate electrodes of the second transistors UT1 and UT2, respectively.

For example, the first transistors LT1 and LT2 may include a first erase control transistor LT1 and a ground selection transistor LT2 that are connected in series. The second transistors UT1 and UT2 may include a string selection transistor UT1 and a second erase control transistor UT2 that are connected in series. One or both of the first and second erase control transistors LT1 and UT2 may be employed to perform an erase operation in which a gate induced drain leakage (GIDL) phenomenon is used to erase data stored in the memory cell transistors MCT.

The common source line CSL, the first lines LL1 and LL2, the word lines WL, and the second lines UL1 and UL2 may be electrically connected to the decoder circuit 1110 through first connection lines 1115 that extend from the first region 1100F toward the second region 1100S. The bit lines BL may be electrically connected to the page buffer 1120 through second connection lines 1125 that extend from the first region 1100F toward the second region 1100S.

On the first region 1100F, the decoder circuit 1110 and the page buffer 1120 may perform a control operation on at least one selection memory cell transistor among the plurality of memory cell transistors MCT. The logic circuit 1130 may control the decoder circuit 1110 and the page buffer 1120. The three-dimensional semiconductor memory device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first region 1100F toward the second region 1100S.

The controller 1200 may include a processor 1210, a NAND controller 1220, and a host interface 1230. For example, the electronic system 1000 may include a plurality of three-dimensional semiconductor memory devices 1100, and in this case, the controller 1200 may control the plurality of three-dimensional semiconductor memory devices 1100.

The processor 1210 may control an overall operation of the electronic system 1000 that includes the controller 1200. The processor 1210 may operate based on certain firmware, and may control the NAND controller 1220 to access the three-dimensional semiconductor memory device 1100. The NAND controller 1220 may include an NAND interface 1221 that processes communication with the three-dimensional semiconductor memory device 1100. The NAND interface 1221 may be used to transfer therethrough a control command which is intended to control the three-dimensional semiconductor memory device 1100, data which is intended to be written on the memory cell transistors MCT of the three-dimensional semiconductor memory device 1100, and/or data which is intended to be read from the memory cell transistors MCT of the three-dimensional semiconductor memory device 1100. The host interface 1230 may provide the electronic system 1000 with communication with an external host. When a control command is received through the host interface 1230 from an external host, the three-dimensional semiconductor memory device 1100 may be controlled by the processor 1210 in response to the control command.

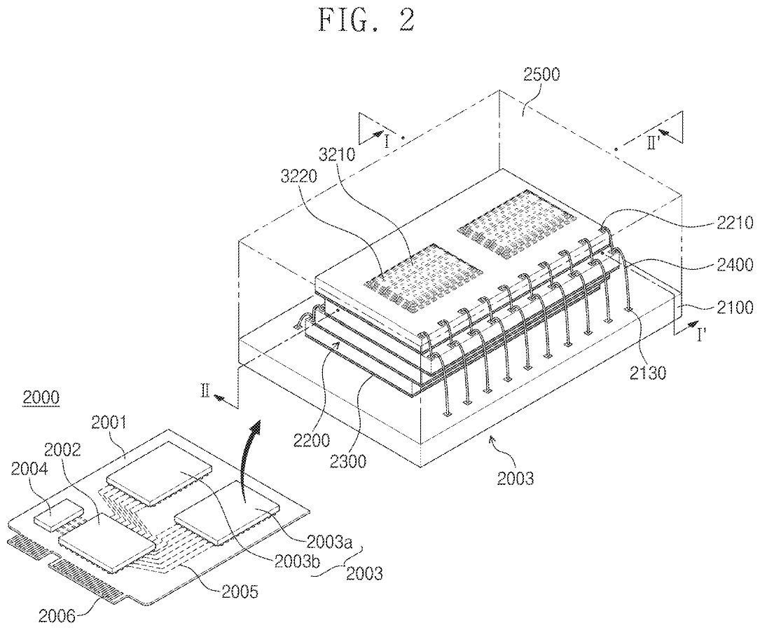

FIG. 2 illustrates a simplified perspective view showing an electronic system that includes a three-dimensional semiconductor memory device according to some implementations of the present inventive concepts.

Referring to FIG. 2, an electronic system 2000 according to some implementations of the present inventive concepts includes a main board 2001, a controller 2002 mounted on the main board 2001, one or more semiconductor packages 2003, and a dynamic random access memory (DRAM) 2004. The semiconductor package 2003 and the DRAM 2004 may be connected to the controller 2002 through wiring patterns 2005 provided in the main board 2001.

The main board 2001 may include a connector 2006 including a plurality of pins that are coupled to an external host. The number and arrangement of the plurality of pins in the connector 2006 may be changed based on a communication interface between the electronic system 2000 and the external host. The electronic system 2000 may communicate with the external host through one or more interfaces, for example, universal serial bus (USB), peripheral component interconnect express (PIC-Express), serial advanced technology attachment (SATA), and M-PHY for universal flash storage (UFS). For example, the electronic system 2000 may operate with power that is supplied through the connector 2006 from the external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

The semiconductor package 2003 may include first and second semiconductor packages 2003a and 2003b that are spaced apart from each other. Each of the first and second semiconductor packages 2003a and 2003b may include a plurality of semiconductor chips 2200. Each of the first and second semiconductor packages 2003a and 2003b may include a package substrate 2100, semiconductor chips 2200 on the package substrate 2100, adhesion layers 2300 on bottom surfaces of the semiconductor chips 2200, connection structures 2400 that electrically connect the semiconductor chips 2200 to the package substrate 2100, and a molding layer 2500 that lies on the package substrate 2100 and covers the semiconductor chips 2200 and the connection structures 2400.

The package substrate 2100 may be an integrated circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stack structures 3210 and vertical channel structures 3220. Each of the semiconductor chips 2200 may include a three-dimensional semiconductor memory device which will be discussed below.

For example, the connection structures 2400 may be bonding wires that electrically connect the input/output pads 2210 to the package upper pads 2130. On each of the first and second semiconductor packages 2003a and 2003b, the semiconductor chips 2200 may be electrically connected to each other in a wire bonding manner, and may be electrically connected to the package upper pads 2130 of the package substrate 2100. In some implementations, on each of the first and second semiconductor packages 2003a and 2003b, the semiconductor chips 2200 may be electrically connected to each other using through-silicon vias (TSVs) instead of the connection structures 2400 or the bonding wires.

For example, the controller 2002 and the semiconductor chips 2200 may be included in a single package. For example, the controller 2002 and the semiconductor chips 2200 may be mounted on a separate interposer substrate other than the main board 2001, and may be connected to each other through lines provided in the interposer substrate.

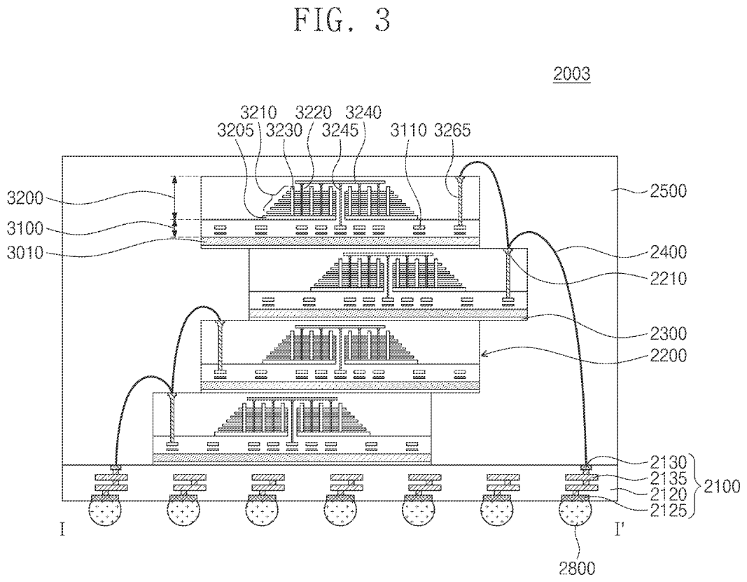

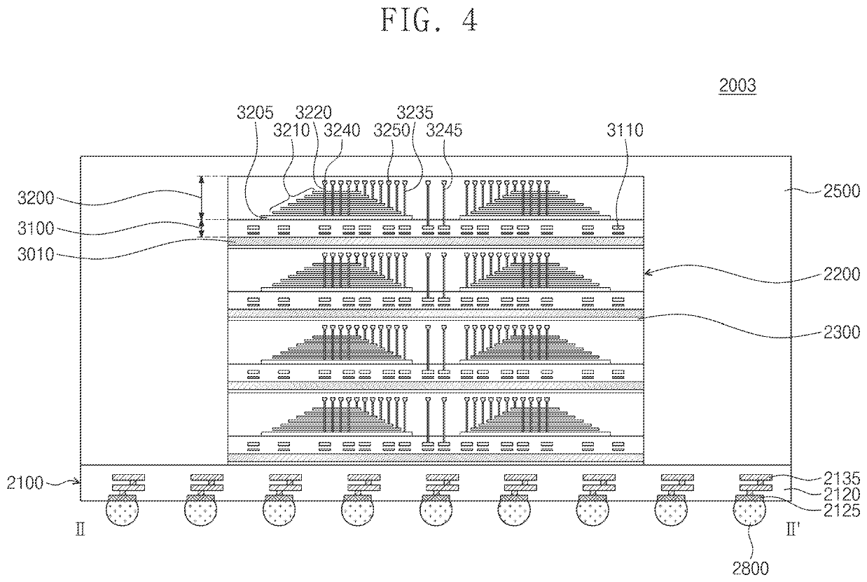

FIGS. 3 and 4 illustrate cross-sectional views respectively taken along lines I-I′ and II-II′ of FIG. 2, showing a semiconductor package that includes a three-dimensional semiconductor memory device according to some implementations of the present inventive concepts.

Referring to FIGS. 3 and 4, a semiconductor package 2003 includes a package substrate 2100, a plurality of semiconductor chips on the package substrate 2100, and a molding layer 2500 that covers the package substrate 2100 and the plurality of semiconductor chips.

The package substrate 2100 may include a package substrate body 2120, package upper pads 2130 disposed on a top surface of the package substrate body 2120, package lower pads 2125 disposed or exposed on a bottom surface of the package substrate body 2120, and internal wiring lines 2135 that lie in the package substrate body 2120 and electrically connect the package upper pads 2130 to the package lower pads 2125. The package upper pads 2130 may be electrically connected to a plurality of connection structures 2400. The package lower pads 2125 may be connected through conductive connectors 2800 to the wiring patterns 2005 in the main board 2001 of the electronic system 2000 depicted in FIG. 2.

Each of the semiconductor chips 2200 may include a semiconductor substrate 3010, and may also include a first structure 3100 and a second structure 3200 that are sequentially stacked on the semiconductor substrate 3010. The first structure 3100 may include a peripheral circuit region including peripheral wiring lines 3110. The second structure 3200 may include a common source line 3205, a gate stack structure 3210 on the common source line 3205, vertical channel structures 3220 and separation structure 3230 that penetrate the gate stack structure 3210, bit lines 3240 electrically connected to the vertical channel structures 3220, gate connection lines 3235 and conductive lines 3250 that are electrically connected to word lines (see WL of FIG. 1) of the gate stack structure 3210.

Each of the semiconductor chips 2200 may include one or more through wiring lines 3245 that extend into the second structure 3200 and are electrically connected to the peripheral wiring lines 3110 of the first structure 3100. The through wiring line 3245 may penetrate the gate stack structure 3210, and may further be disposed outside the gate stack structure 3210. Each of the semiconductor chips 2200 may further include an input/output connection line 3265 that extends into the second structure 3200 and is electrically connected to the peripheral wiring lines 3110 of the first structure 3100, and may also further include input/output pads 2210 electrically connected to the input/output connection line 3265.

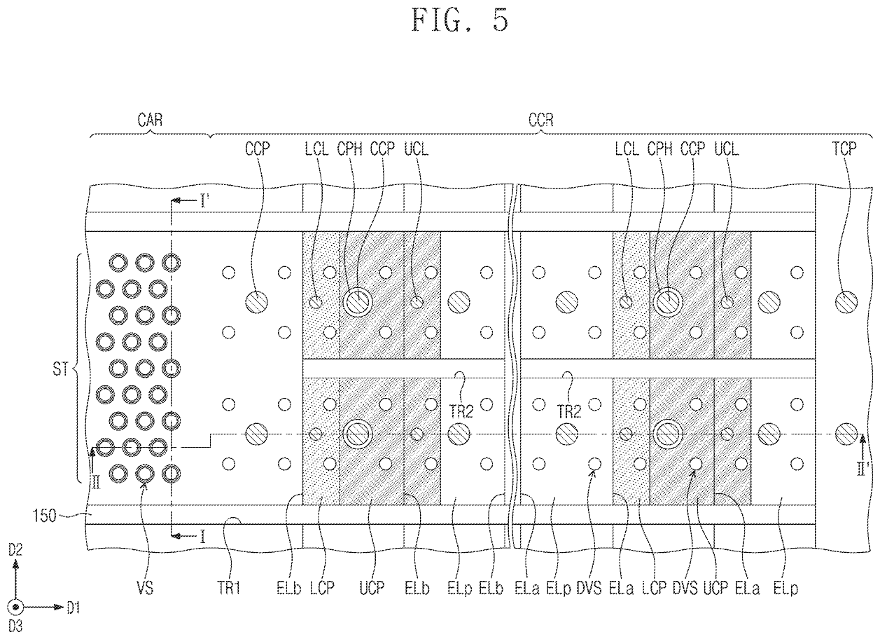

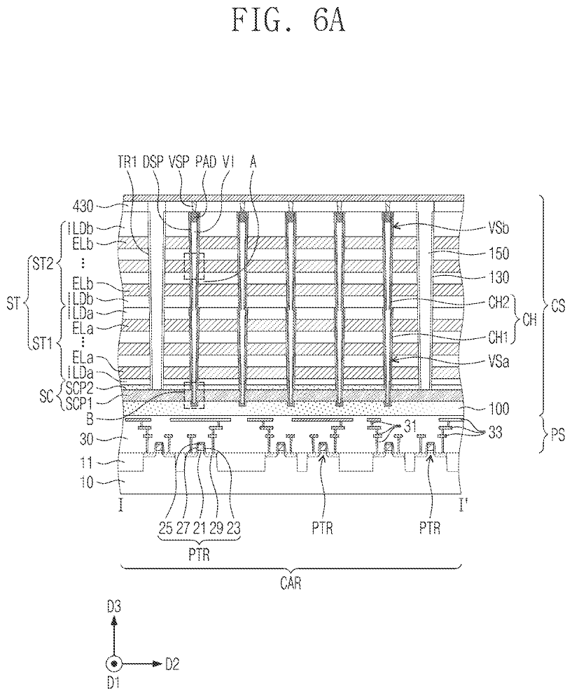

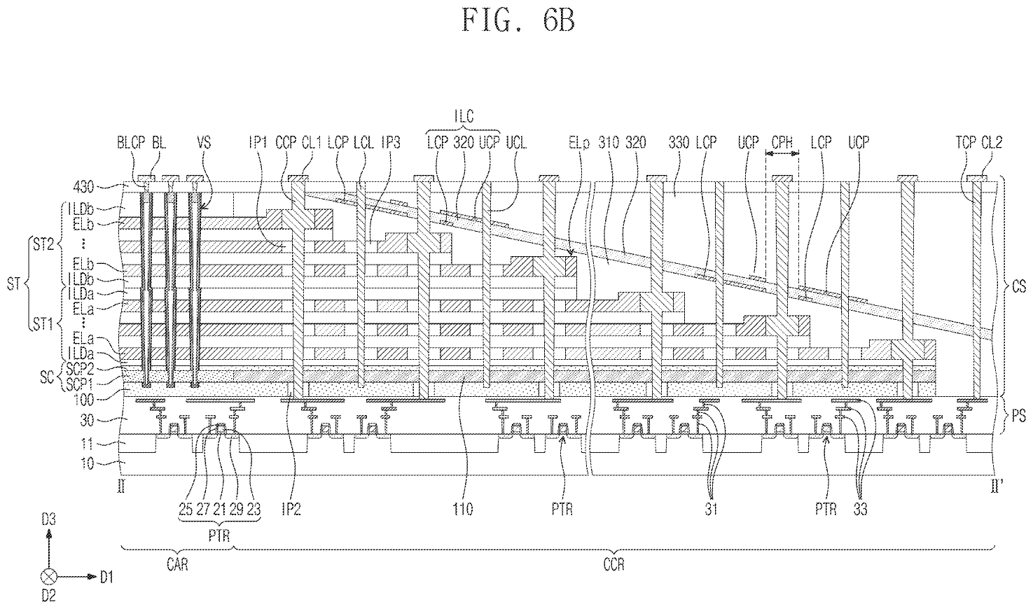

FIG. 5 illustrates a plan view showing a three-dimensional semiconductor memory device according to some implementations of the present inventive concepts. FIGS. 6A and 6B illustrate cross-sectional views respectively taken along lines I-I′ and II-II′ of FIG. 5, showing a three-dimensional semiconductor memory device according to some implementations of the present inventive concepts.

Referring to FIGS. 5, 6A, and 6B, a three-dimensional semiconductor memory device according to the present inventive concepts includes a first substrate 10, a peripheral circuit structure PS on the first substrate 10, and a cell array structure CS on the peripheral circuit structure PS. The first substrate 10, the peripheral circuit structure PS, and the cell array structure CS may respectively correspond to the semiconductor substrate 3010, the first structure 3100 on the semiconductor substrate 3010, and the second structure 3200 on the first structure 3100 of FIGS. 3 and 4.

The first substrate 10 may be provided which includes a cell array region CAR and a contact region CCR. The first substrate 10 may extend in a first direction D1 directed from the cell array region CAR toward the contact region CCR and in a second direction D2 that intersects the first direction D1. The first direction D1 and the second direction D2 may be parallel to a top surface of the first substrate 10. A third direction D3 may be perpendicular to the top surface of the first substrate 10. For example, the first, second, and third directions D1, D2, and D3 may be orthogonal to each other.

When viewed in plan, the contact region CCR may extend in the first direction D1 (or a direction opposite to the first direction D1) from the cell array region CAR. The cell array region CAR may be an area on which are provided the vertical channel structure 3220, the separation structures 3230, and the bit lines 3240 electrically connected to the vertical channel structures 3220, which components 3220, 3230, and 3240 are discussed with reference to FIGS. 3 and 4. The contact region CCR may be an area on which is provided a stepwise structure including pads parts ELp which will be discussed below. Different from that shown, the contact region CCR may extend in the second direction D2 (or a direction opposite to the second direction D2) from the cell array region CAR.

The first substrate 10 may be, for example, a silicon substrate, a silicon-germanium substrate, a germanium substrate, or a monocrystalline epitaxial layer grown on a monocrystalline silicon substrate. A device isolation layer 11 may be provided in the first substrate 10. The device isolation layer 11 may define an active section of the first substrate 10. The device isolation layer 11 may include, for example, silicon oxide.

The peripheral circuit structure PS may be provided on the first substrate 10. The peripheral circuit structure PS may include peripheral circuit transistors PTR on the active section of the first substrate 10, peripheral contact plugs 31, peripheral circuit lines 33 electrically connected through the peripheral contact plugs 31 to the peripheral circuit transistors PTR, and a lower dielectric layer 30 that surrounds the peripheral circuit transistors PTR, the peripheral contact plugs 31, and the peripheral circuit lines 33. The peripheral circuit structure PS may correspond to the first region 1100F of FIG. 1, and the peripheral circuit lines 33 may correspond to the peripheral wiring lines 3110 of FIGS. 3 and 4.

A peripheral circuit may be constituted by the peripheral circuit transistors PTR, the peripheral contact plugs 31, and the peripheral circuit lines 33. For example, the peripheral circuit transistors PTR may constitute the decoder circuit 1110, the page buffer 1120, and the logic circuit 1130 of FIG. 1. In more detail, each of the peripheral circuit transistors PTR may include a peripheral gate dielectric layer 21, a peripheral gate electrode 23, a peripheral capping pattern 25, a peripheral gate spacer 27, and peripheral source/drain sections 29.

The peripheral gate dielectric layer 21 may be provided between the peripheral gate electrode 23 and the first substrate 10. The peripheral capping pattern 25 may be provided on the peripheral gate electrode 23. The peripheral gate spacer 27 may cover a sidewall of the peripheral gate dielectric layer 21, a sidewall of the peripheral gate electrode 23, and a sidewall of the peripheral capping pattern 25. The peripheral source/drain sections 29 may be provided in the first substrate 10 adjacent to opposite sides of the peripheral gate electrode 23.

The peripheral circuit lines 33 may be electrically connected through the peripheral contact plugs 31 to the peripheral circuit transistors PTR. Each of the peripheral circuit transistors PTR may be, for example, an NMOS transistor, a PMOS transistor, or a gate-all-around type transistor. For example, the peripheral contact plugs 31 may each have a width in the first direction D1 or the second direction D2, and the width may increase with increasing distance from the first substrate 10. The peripheral contact plugs 31 and the peripheral circuit lines 33 may include a conductive material, such as metal.

The lower dielectric layer 30 may be disposed on the top surface of first substrate 10. On the first substrate 10, the lower dielectric layer 30 may cover the peripheral circuit transistors PTR, the peripheral contact plugs 31, and the peripheral circuit lines 33. The lower dielectric layer 30 may include a plurality of dielectric layers that constitute a multi-layered structure. For example, the lower dielectric layer 30 may include one or more of silicon oxide, silicon nitride, silicon oxynitride, and low-k dielectric materials.

The lower dielectric layer 30 may be provided thereon with the cell array structure CS that includes a second substrate 100 and a stack structure ST on the second substrate 100. The second substrate 100 may extend in the first and second directions D1 and D2. The second substrate 100 may not be provided on a partial area of the contact region CCR. The second substrate 100 may be a semiconductor substrate including a semiconductor material. The second substrate 100 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof.

The stack structure ST may be provided on the second substrate 100. The stack structure ST may extend from the cell array region CAR toward the contact region CCR. The stack structure ST may correspond to the gate stack structure 3210 of FIGS. 3 and 4. The stack structure ST may be provided in plural, and the plurality of stack structures ST may be arranged along the second direction D2 and spaced apart in the second direction D2 from each other across a separation structure 150 which will be discussed below. For convenience of description, the following explanation will focus on a single stack structure ST, but this explanation may also be applicable to other stack structures ST.

The stack structure ST may include interlayers ILDa and ILDb and gate electrodes ELa and ELb that are alternately stacked. The gate electrodes ELa and ELb may correspond to the word lines WL, the first lines LL1 and LL2, and the second lines UL1 and UL2 of FIG. 1.

The stack structure ST may include, for example, a first stack structure ST1 on the second substrate 100 and a second stack structure ST2 on the first stack structure ST1. The first stack structure ST1 may include first interlayers ILDa and first gate electrodes ELa that are alternately stacked, and the second stack structure ST2 may include second interlayers ILDb and second gate electrodes ELb that are alternately stacked. The first and second gate electrodes ELa and ELb may have substantially the same thickness in the third direction D3. In this description below, the term “thickness” may indicate a thickness in the third direction D3.

The first and second gate electrodes ELa and ELb may have their lengths in the first direction D1 that decrease with increasing distance (or in the third direction D3) from the second substrate 100. For example, each of the first and second gate electrodes ELa and ELb may have a length in the first direction D1 that is greater than a length in the first direction D1 of an immediately overlying gate electrode. A lowermost one of the first gate electrodes ELa included in the first stack structure ST1 may have a maximum length in the first direction D1, and an uppermost one of the second gate electrodes ELb included in the second stack structure ST2 may have a minimum length in the first direction D1.

The first and second gate electrodes ELa and ELb may have their pad parts ELp on the contact region CCR. The pad parts ELp of the first and second gate electrodes ELa and ELb may be disposed at their positions that are horizontally and vertically different from each other. The pad parts ELp may form a stepwise structure along the first direction D1 on the contact region CCR.

The stepwise structure may be arranged such that each of the first and second stack structures ST1 and ST2 may have a thickness which decreases with increasing distance from an outermost one of vertical channel structures VS which will be discussed below, and such that the first and second gate electrodes ELa and ELb may have their sidewalls spaced apart at a regular interval from each other along the first direction D1 when viewed in plan.

The first and second electrodes ELa and ELb may include, for example, at least one selected from doped semiconductors (e.g., doped silicon, etc.), metals (e.g., tungsten, copper, aluminum, etc.), conductive metal nitrides (e.g., titanium nitride, tantalum nitride, etc.), and transition metals (e.g., titanium, tantalum, etc.). For example, the first and second gate electrodes ELa and ELb may include tungsten.

The first and second interlayers ILDa and ILDb may be provided between the first and second gate electrodes ELa and ELb, and may each have a sidewall aligned with that of an overlaying one of the first and second gate electrodes ELa and ELb. For example, likewise the first and second gate electrodes ELa and ELb, the first and second interlayers ILDa and ILDb may have their lengths in the first direction D1 that decrease with increasing distance from the second substrate 100.

A lowermost one of the second interlayers ILDb may be in contact with an uppermost one of the first interlayers ILDa. For example, each of the first and second interlayers ILDa and ILDb may have a thickness less than that of each of the first and second gate electrodes ELa and ELb. For example, a lowermost one of the first interlayers ILDa may have a thickness less than that of each of other interlayers ILDa and ILDb. For example, an uppermost one of the second interlayers ILDb may have a thickness greater than that of each of other interlayers ILDa and ILDb.

Except the lowermost first interlayers ILDa and the uppermost second interlayers ILDb, other interlayers ILDa and ILDb may have substantially the same thickness. This, however, is merely an example, and the first and second interlayers ILDa and ILDb may have their thicknesses that are changed based on properties of a semiconductor device.

The first and second interlayers ILDa and ILDb may include, for example, one or more of silicon oxide, silicon nitride, silicon oxynitride, and low-k dielectric materials. For example, the first and second interlayers ILDa and ILDb may include high-density plasma (HDP) oxide or tetraethylorthosilicate (TEOS).

A source structure SC may be provided between the lowermost first interlayer ILDa and the second substrate 100 on the cell array region CAR. The source structure SC may correspond to the common source line CSL of FIG. 1 or the common source line 3205 of FIGS. 3 and 4. The source structure SC may include a first source conductive pattern SCP1 and a second source conductive pattern SCP2 that are sequentially stacked on the second substrate 100. The second source conductive pattern SCP2 may be provided between the first source conductive pattern SCP1 and the lowermost first interlayer ILDa. The first source conductive pattern SCP1 may have a thickness greater than that of the second source conductive pattern SCP2. The first and second source conductive patterns SCP1 and SCP2 may include a semiconductor material such as silicon or a semiconductor material doped with impurities. When the first and second source conductive patterns SCP1 and SCP2 include an impurity-doped semiconductor material, the first source conductive pattern SCP1 may have an impurity concentration greater than that of the second source conductive pattern SCP2. According to some implementations, on the contact region CCR, a dummy dielectric pattern 110 may be provided between the second substrate 100 and the stack structure ST. The dummy dielectric pattern 110 may be located at substantially the same level as that of the first source conductive pattern SCP1. The dummy dielectric pattern 110 may be a multi-layered dielectric pattern including different materials. The dummy dielectric pattern 110 may include, for example, at least one selected from a silicon oxide layer, a silicon nitride layer, a silicon oxynitride layer, a silicon carbide layer, and a silicon-germanium layer.

The first source conductive pattern SCP1 of the source structure SC may be provided only on the cell array region CAR, but not on the contact region CCR. The second source conductive pattern SCP2 of the source structure SC may extend from the cell array region CAR to the contact region CCR.

On the cell array region CAR, a plurality of vertical channel structures VS may be provided to penetrate the stack structure ST and the source structure SC. The vertical channel structures VS may penetrate at least a portion of the second substrate 100, and each of the vertical channel structures VS may have a bottom surface located at a lower level than that of a top surface of the second substrate 100 and that of a bottom surface of the source structure SC. For example, the vertical channel structures VS may be in direct contact with the second substrate 100.

When viewed in plan as shown in FIG. 5, the vertical channel structures VS may be arranged in a zigzag fashion along the first direction D1 or the second direction D2. The vertical channel structures VS may not be provided on the contact region CCR. The vertical channel structures VS may correspond to the vertical channel structures 3220 of FIGS. 2 to 4. The vertical channel structures VS may correspond to channels of the first transistors LT1 and LT2, channels of the memory cell transistors MCT, and channels of the second transistors UT1 and UT2, which transistors LT1, LT2, MCT, UT1, and UT2 are depicted in FIG. 1.

The vertical channel structures VS may be provided in vertical channel holes CH that penetrate the stack structure ST. Each of the vertical channel holes CH may include a first vertical channel hole CH1 that penetrates the first stack structure ST1 and a second vertical channel hole CH2 that penetrates the second stack structure ST2. The first and second vertical channel holes CH1 and CH2 of each of the vertical channel holes CH may be connected to each other in the third direction D3.

Each of the vertical channel structures VS may include a first part VSa and a second part VSb. The first part VSa may be provided in the first vertical channel hole CH1, and the second part VSb may be provided in the second vertical channel hole CH2. The second part VSb may be provided on and connected to the first part VSa.

The first part VSa and the second part VSb may each have a width in the first direction D1 or the second direction D2 that increases in the third direction D3. An uppermost portion of the first part VSa may have a width greater than that of a lowermost portion of the second part VSb. For example, each of the vertical channel structures VS may have a sidewall that has a step difference at a boundary between the first part VSa and the second part VSb. This, however, is merely an example, and the present inventive concepts are not limited thereto. For example, each of the vertical channel structures VS may have a sidewall that has three or more step differences at different levels or may have a flat sidewall with no step difference.

Each of the vertical channel structures VS may include a data storage pattern DSP and a vertical semiconductor pattern VSP that are sequentially provided on an inner sidewall of the vertical channel holes CH, a buried dielectric pattern VI that fills an inner space surrounded by the vertical semiconductor pattern VSP, and a conductive pad PAD on the buried dielectric pattern VI. The conductive pad PAD may be provided in a space surrounded by the buried dielectric pattern VI and the data storage pattern DSP (or the vertical semiconductor pattern VSP). The vertical channel structures VS may each have a top surface that has, for example, a circular shape, an oval shape, or a bar shape. The data storage pattern DSP may be adjacent to the stack structure ST to cover sidewalls of the first and second interlayers ILDa and ILDb and sidewalls of the first and second gate electrodes ELa and ELb. The vertical semiconductor pattern VSP may conformally cover an inner sidewall of the data storage pattern DSP.

The vertical semiconductor pattern VSP may be provided between the data storage pattern DSP and the buried dielectric pattern VI. The vertical semiconductor pattern VSP may have a macaroni shape or a pipe shape whose bottom end is closed. The data storage pattern DSP may have a macaroni shape or a pipe shape whose bottom end is opened.

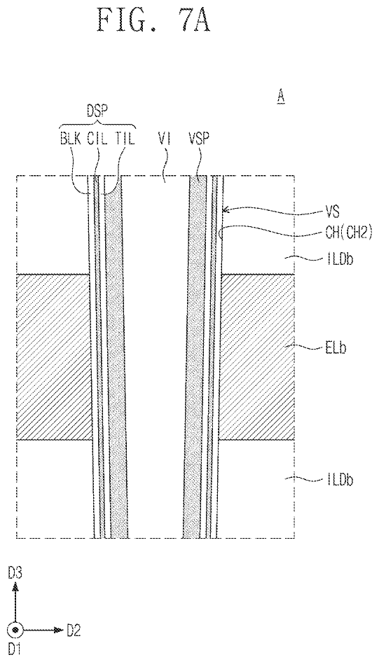

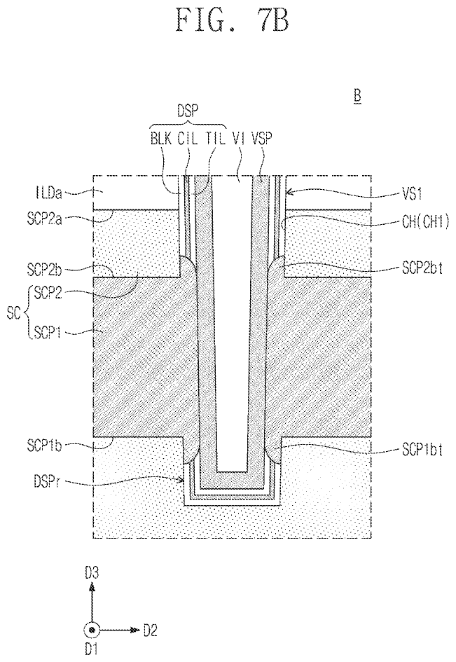

The vertical semiconductor pattern VSP may include, for example, an impurity-doped semiconductor material, an impurity-undoped intrinsic semiconductor material, or a polycrystalline semiconductor material. As discussed below with reference to FIG. 7B, the vertical semiconductor pattern VSP may be in contact with a portion of the source structure SC. The conductive pad PAD may include, for example, an impurity-doped semiconductor material or a conductive material.

The contact region CCR may include a plurality of dummy vertical channel structures DVS that penetrate a second dielectric layer 330, a first interlayer dielectric layer 320, a first dielectric layer 310, the stack structure ST, the second source conductive pattern SCP2, and the dummy dielectric pattern 110. For example, the dummy vertical channel structures DVS may penetrate the pad parts ELp of the first and second gate electrodes ELa and ELb. The dummy vertical channel structures DVS may be provided around cell contact plugs CP which will be discussed. The dummy vertical channel structures DVS may not be provided on the cell array region CAR. According to some implementations, the dummy vertical channel structures DVS may not be provided.

On the contact region CCR, the first dielectric layer 310 may be provided to cover the stack structure ST and a portion of the lower dielectric layer 30. For example, the first dielectric layer 310 may cover the stepwise structure of the stack structure ST, and may be provided on the pad parts ELp of the first and second gate electrodes ELa and ELb. The first dielectric layer 310 may have a top surface that is inclined along the pad part ELp of the stack structure ST. For example, the top surface of the first dielectric layer 310 may become lower in the first direction D1.

A lower electrode plate LCP may be disposed on the first dielectric layer 310 on the pad part ELp. The lower electrode plate LCP may have a contact separation hole CPH therein, and the contact separation hole CPH may electrically separate the lower electrode plate LCP from a cell contact plug CCP which will be discussed below.

The first interlayer dielectric layer 320 may be provided to cover the first dielectric layer 310 and the lower electrode plate LCP on the contact region CCR. The first interlayer dielectric layer 320 may have a top surface that becomes lower in the first direction D1 along the pad part ELp of the stack structure ST.

An upper electrode plate UCP may be disposed on the first interlayer dielectric layer 320 on the pad part ELp. The upper electrode plate UCP may have a contact separation hole CPH therein, and the contact separation hole CPH may electrically separate the upper electrode plate UCP from a cell contact plug CCP which will be discussed below. When viewed in plan, the contact separation hole CPH in the upper electrode plate UCP may be provided at substantially the same position as that of the contact separation hole CPH in the lower electrode plate LCP.

The lower electrode plate LCP and the upper electrode plate UCP may include at least one metal, such as aluminum, copper, tungsten, molybdenum, and cobalt.

An interlayer capacitor ILC may be constituted by the lower electrode plate LCP, the upper electrode plate UCP, and the first interlayer dielectric layer 320 between the lower electrode plate LCP and the upper electrode plate UCP. A plurality of interlayer capacitors ILC may be disposed between the first dielectric layer 310 and the second dielectric layer 330, and each of the plurality of interlayer capacitors ILC may vertically overlap the pad part ELp of the stack structure ST. As the interlayer capacitor ILC is disposed on the pad part ELp of the stack structure ST, it may be possible to utilize a space formed of only ordinary dielectric layers and as a result to reduce a size of the three-dimensional semiconductor memory device.

On the contact region CCR, the second dielectric layer 330 may be provided to cover the first interlayer dielectric layer 320 and the upper electrode plate UCP. The second dielectric layer 330 may have a top surface that is substantially flat. The top surface of the second dielectric layer 330 may be substantially coplanar with an uppermost surface of the stack structure ST.

Each of the second and third dielectric layers 310 and 330 may include one dielectric layer or a plurality of stacked dielectric layers. The second and third dielectric layers 310 and 330 may include a dielectric material, such as silicon oxide, silicon nitride, silicon oxynitride, and low-k dielectric materials. The second and third dielectric layers 310 and 330 may include a dielectric material different from that of the first and second interlayers ILDa and ILDb of the stack structure ST. For example, when the first and second interlayers ILDa and ILDb of the stack structure ST include high-density plasma oxide, the second and third dielectric layers 310 and 330 may include tetraethylorthosilicate (TEOS).

The first interlayer dielectric layer 320 may include a material that serves as a dielectric layer of the interlayer capacitor ILC. For example, the first interlayer dielectric layer 320 may include silicon oxide.

A fourth dielectric layer 430 may be provided on the stack structure ST, the first dielectric layer 310, the first interlayer dielectric layer 320, and the second dielectric layer 330. The fourth dielectric layer 430 may cover a top surface of the uppermost second interlayer ILDb of the stack structure ST, the top surface of the first dielectric layer 310, the top surface of the first interlayer dielectric layer 320, the top surface of the second dielectric layer 330, and the top surface of the vertical channel structure VS.

The fourth dielectric layer 430 may include a single dielectric layer or a plurality of stacked dielectric layers. The fourth dielectric layer 430 may include, for example, one or more of silicon oxide, silicon nitride, silicon oxynitride, and low-k dielectric materials. The fourth dielectric layer 430 may include a dielectric material substantially the same as that of the second and third dielectric layers 310 and 330 and different from that of the first and second interlayers ILDa and ILDb of the stack structure ST.

When the stack structure ST is provided in plural, a first trench TR1 and a second trench TR2 may be provided to run in the first direction D1 across between the plurality of stack structures ST. A separation structure 150 may be provided in the first trench TR1 and the second trench TR2. The first trench TR1 may extend along the first direction D1 from the cell array region CAR toward the contact region CCR of the first substrate 10. The second trench TR2 may be provided on the contact region CCR, while extending along the first direction D1. The separation structure 150 may be spaced apart in the second direction D2 from the vertical channel structures VS. The separation structure 150 may have a top surface located at a higher level than that of the top surfaces of the vertical channel structures VS. The top surface of the separation structure 150 may be coplanar with that of the fourth dielectric layer 430. The separation structure 150 may have a bottom surface which is substantially coplanar with that of the second source conductive pattern SCP2 and which is located at a higher level than that of the top surface of the second substrate 100.

The separation structure 150 may be provided in plural, and the plurality of separation structures 150 may be spaced apart in the second direction D2 from each other across the stack structure ST. The separation structure 150 may correspond to the separation structure 3230 of FIGS. 3 and 4.

The separation structure 150 and the stack structure ST may be provided therebetween with a separation spacer 130 that surrounds the separation structure 150. The separation spacer 130 may conformally cover the sidewalls of the first and second interlayers ILDa and ILDb and the sidewalls of the first and second gate electrodes ELa and ELb. The separation structure 150 may include, for example, silicon oxide. The separation spacer 130 may include a material having an etch selectivity with respect to the second source conductive pattern SCP2 and the dummy dielectric pattern 110. The separation spacer 130 may include, for example, silicon nitride.

Bit-line contact plugs BLCP may be provided which penetrate the fourth dielectric layer 430 to come into connection with the vertical channel structures VS. On the contact region CCR, cell contact plugs CCP may be provided to penetrate the fourth dielectric layer 430, the second dielectric layer 330, the first interlayer dielectric layer 320, the first dielectric layer 310, and the pad part ELp of the stack structure ST and to connect with the first and second gate electrodes ELa and ELb. Each of the cell contact plugs CCP may penetrate the second source conductive pattern SCP2, the dummy dielectric pattern 110, and the second substrate 100 to come into electrical connection with the peripheral circuit structure PS. The cell contact plugs CCP may penetrate the contact separation holes CPH of the lower and upper electrode plates LCP and UCP. The first interlayer dielectric layer 320 may extend into the contact separation hole CPH between the lower electrode plate LCP and the cell contact plug CCP, and the second dielectric layer 330 may extend into the contact separation hole CPH between the upper electrode plate UCP and the cell contact plug CCP. Therefore, the cell contact plug CCP may be electrically separated from the lower electrode plate LCP and the upper electrode plate UCP. The cell contact plugs CCP may correspond to the gate connection lines 3235 of FIG. 4.

Each of the cell contact plugs CCP may be spaced apart in a horizontal direction and electrically separated from the first and second gate electrodes ELa and ELb below the pad parts ELp across a first dielectric pattern IP1, which horizontal direction is one direction on a plane parallel to the first direction D1 and the second direction D2. Each of the cell contact plugs CCP may be spaced apart in the horizontal direction and electrically separated from the second substrate 100 across a second dielectric pattern IP2. The first and second dielectric patterns IP1 and IP2 may include the same material as that of the first and second interlayers ILDa and ILDb of the stack structure ST. Each of the cell contact plugs CCP may have a bottom located at a lower level than that of a bottom surface of the second substrate 100. A height in the third direction D3 of each of the cell contact plugs CCP may be substantially the same as a height in the third direction D3 of a peripheral contact plug TCP.

The peripheral contact plug TCP may be provided to penetrate the fourth dielectric layer 430, the second dielectric layer 330, the first interlayer dielectric layer 320, the first dielectric layer 310, and at least a portion of the lower dielectric layer 30 to come into electrical connection with the peripheral circuit transistors PTR of the peripheral circuit structure PS. Different from that shown, the peripheral contact plug TCP may be provided in plural. The peripheral contact plug TCP may be spaced apart in the first direction D1 from the second substrate 100, the source structure SC, and the stack structure ST. The peripheral contact plug TCP may correspond to the through wiring line 3245 of FIGS. 3 and 4.

On the pad part ELp, there may be provided a lower conductive line LCL and an upper conductive line UCL that penetrate the fourth dielectric layer 430, the second dielectric layer 330, the first interlayer dielectric layer 320, the first dielectric layer 310, and the stack structure ST. The lower conductive line LCL may penetrate and electrically connect with the lower electrode plate LCP. The upper conductive line UCL may penetrate and electrically connect with the upper electrode plate UCP. Each of the lower and upper conductive lines LCL and UCL may be electrically separated and spaced apart from each other in a horizontal direction (or one direction on a plane parallel to the first direction D1 and the second direction D2).

The cell contact plugs CCP, the upper conductive line UCL, the lower conductive line LCL, and the peripheral contact plug TCP may include a conductive pattern including at least one metal selected from aluminum, copper, tungsten, molybdenum, and cobalt and a barrier pattern including a metal layer and a metal nitride layer. The metal layer may include at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PIN) layer.

For example, the bit-line contact plugs BLCP and the peripheral contact plug TCP may each have a width in the first direction D1 or the second direction D2 that increases in the third direction D3.

The fourth dielectric layer 430 may be provided thereon with first conductive lines CL1 and second conductive lines CL2. The first conductive lines CL1 may be electrically connected to corresponding cell contact plugs CCP. The second conductive lines CL2 may be electrically connected to corresponding peripheral contact plugs TCP. The first and second conductive lines CL1 and CL2 may correspond to the conductive lines 3250 of FIG. 4.

The bit-line contact plugs BLCP, the cell contact plugs CCP, the peripheral contact plug TCP, the bit lines BL, and the first and second conductive lines CL1 and CL2 may include a conductive material, such as metal. Although not shown, the fourth dielectric layer 430 may further be provided thereon with additional wiring lines and additional vias that are electrically connected to the bit lines BL and the first and second conductive lines CL1 and CL2.

FIG. 7A illustrates an enlarged view of section A depicted in FIG. 6A, partially showing a three-dimensional semiconductor memory device according to some implementations of the present inventive concepts. FIG. 7B illustrates an enlarged view of section B depicted in FIG. 6A, partially showing a three-dimensional semiconductor memory device according to some implementations of the present inventive concepts.

Referring to FIGS. 6A, 7A, and 7B, the source structure SC is illustrated, which includes the first and second source conductive patterns SCP1 and SCP2, and one of the vertical channel structures VS is illustrated, which includes the data storage pattern DSP, the vertical semiconductor pattern VSP, the buried dielectric pattern VI, and a lower data storage pattern DSPr. For convenience of description, the following explanation will focus on a single stack structure ST and a single vertical channel structure VS, but this explanation may also be applicable to other vertical channel structures VS that penetrate other stack structures ST.

The data storage pattern DSP may include a blocking dielectric layer BLK, a charge storage layer CIL, and a tunneling dielectric layer TIL that are sequentially stacked. The blocking dielectric layer BLK may be adjacent to the stack structure ST or the source structure SC, and the tunneling dielectric layer TIL may be adjacent to the vertical semiconductor pattern VSP. The charge storage layer CIL may be interposed between the blocking dielectric layer BLK and the tunneling dielectric layer TIL. The blocking dielectric layer BLK may conformally cover the inner sidewall of the vertical channel hole CH.

The blocking dielectric layer BLK, the charge storage layer CIL, and the tunneling dielectric layer TIL may extend in the third direction D3 between the vertical semiconductor pattern VSP and the first and second gate electrodes ELa and ELb and between the vertical semiconductor pattern VSP and the first and second interlayers ILDa and ILDb. The data storage pattern DSP may store and/or change data by using Fowler-Nordheim tunneling induced by a voltage difference between the vertical semiconductor pattern VSP and the first and second gate electrodes ELa and ELb. For example, the blocking dielectric layer BLK and the tunneling dielectric layer TIL may include silicon oxide, and the charge storage layer CIL may include silicon nitride or silicon oxynitride.

The first source conductive pattern SCP1 of the source structure SC may be in contact with the vertical semiconductor pattern VSP, and the second source conductive pattern SCP2 of the source structure SC may be spaced apart from the vertical semiconductor pattern VSP across the data storage pattern DSP. The first source conductive pattern SCP1 may be spaced apart from the buried dielectric pattern VI across the vertical semiconductor pattern VSP.

For example, the first source conductive pattern SCP1 may include protrusions SCP1bt and SCP2bt that are located at a level higher than that of a bottom surface SCP2b of the second source conductive pattern SCP2 or lower than that of a bottom surface SCP1b of the first source conductive pattern SCP1. The protrusions SCP1bt and SCP2bt may be located at a level lower than that of a top surface SCP2a of the second source conductive pattern SCP2. The protrusions SCP1bt and SCP2bt may each have, for example, a curved shape at a surface in contact with the data storage pattern DSP or the lower data storage pattern DSPr.

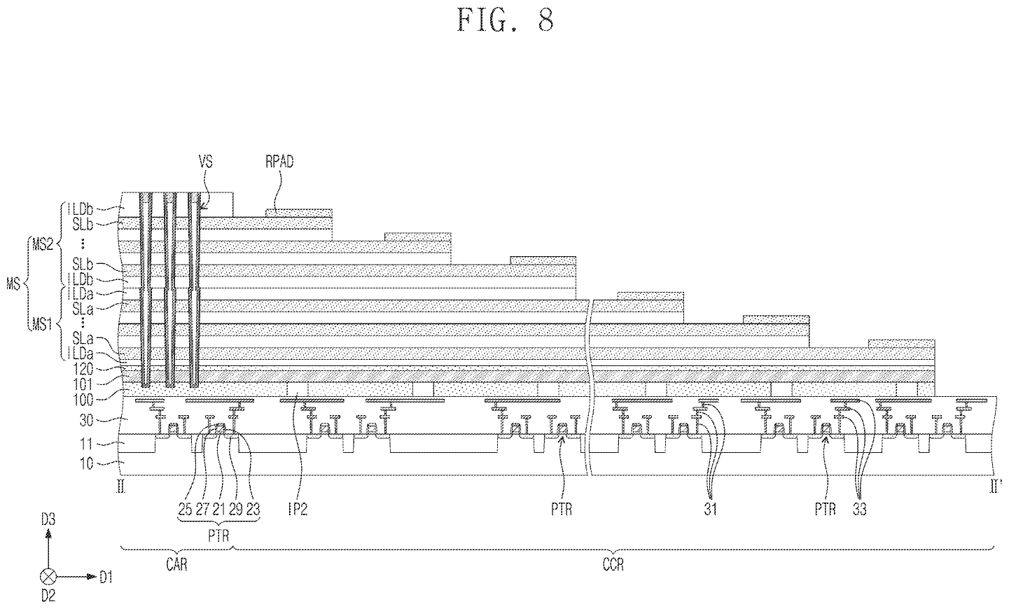

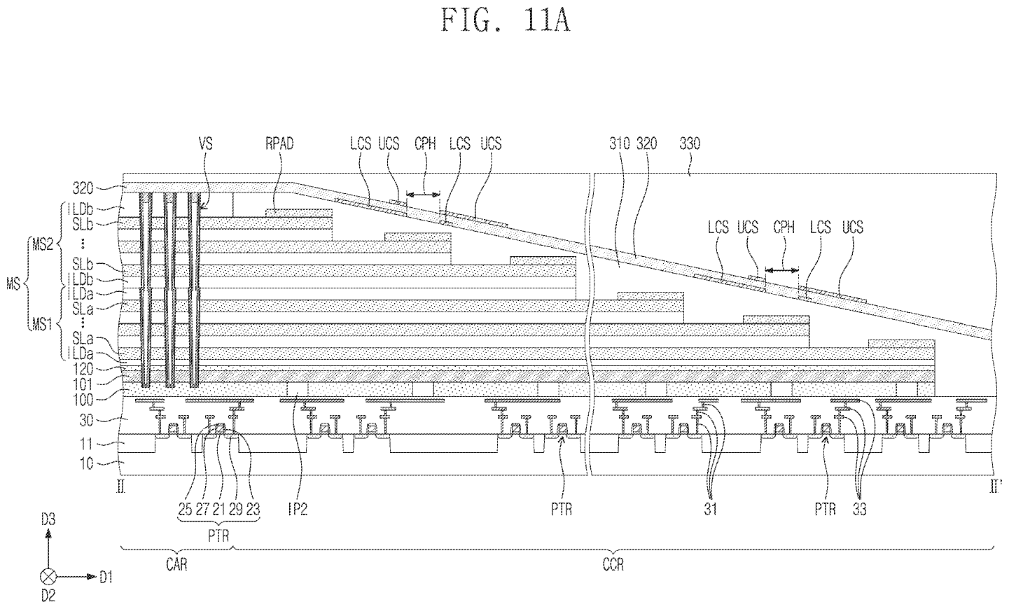

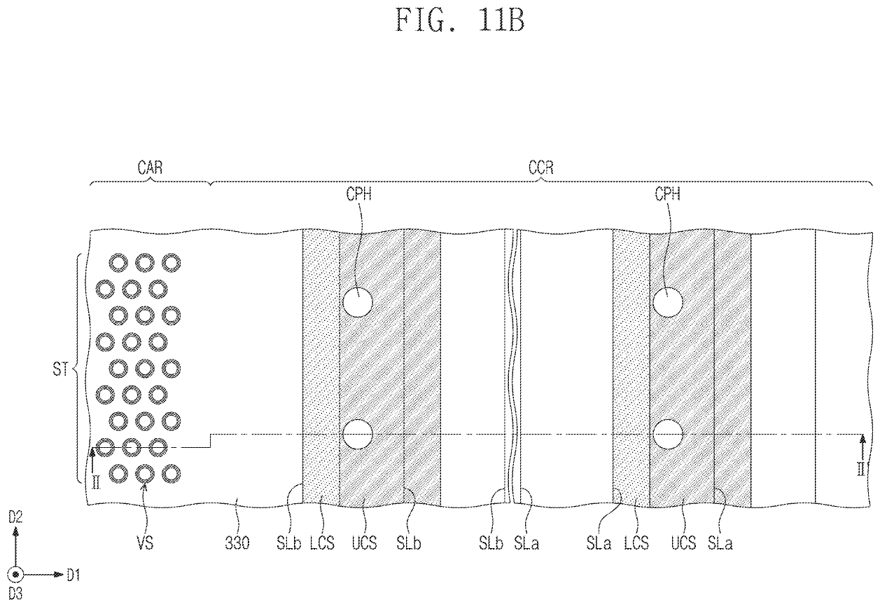

FIGS. 8 to 10, 11A, 12, 13A, 14, 15A, and 16 to 19 illustrate cross-sectional views taken along line II-II′ of FIG. 5, showing a method of fabricating a three-dimensional semiconductor memory device according to some implementations of the present inventive concepts. FIGS. 11B, 13B, and 15B illustrate plan views of FIGS. 11A, 13A, and 15A, respectively. With reference to FIGS. 5, 6A, 6B, and 8 to 19, the following will describe in detail a method of fabricating a three-dimensional semiconductor memory device according to some implementations of the present inventive concepts.

Referring to FIGS. 5 and 8, a first substrate 10 is provided which includes a cell array region CAR and a contact region CCR. A device isolation layer 11 defining an active section may be formed in the first substrate 10. The device isolation layer 11 may be formed by forming a trench on an upper portion of the first substrate 10 and filling the trench with silicon oxide.

Peripheral circuit transistors PTR may be formed on the active section defined by the device isolation layer 11. Peripheral contact plugs 31 and peripheral circuit lines 33 may be formed to be connected to peripheral source/drain sections 29 of the peripheral circuit transistors PTR. A lower dielectric layer 30 may be formed to cover the peripheral circuit transistors PTR, the peripheral contact plugs 31, and the peripheral circuit lines 33.

A second substrate 100 may be formed on the lower dielectric layer 30. The second substrate 100 may extend from the cell array region CAR toward the contact region CCR. Second dielectric patterns IP2 may be formed in the second substrate 100.

A portion of the second substrate 100 may be removed from the contact region CCR. The partial removal of the second substrate 100 may include forming a mask pattern that covers the cell array region CAR and a portion of the contact region CCR, and then using the mask pattern to pattern the second substrate 100. The partial removal of the second substrate 100 may include forming a space where a peripheral contact plug TCP will be provided as discussed below.

A lower sacrificial layer 101, a lower semiconductor layer 120, and a mold structure MS may be formed on the second substrate 100. The second substrate 100 and the lower semiconductor layer 120 may be formed of a semiconductor material doped with impurities. The lower sacrificial layer 101 may be formed of, for example, silicon nitride. Alternatively, the lower sacrificial layer 101 may be formed of a plurality of stacked dielectric layers.

The formation of the mold structure MS may include forming a first mold structure MS1, and forming a second mold structure MS2 on the first mold structure MS1. The formation of the first mold structure MS1 may include sequentially stacking first interlayers ILDa and first sacrificial layers SLa, forming first vertical channel holes CH1 that penetrate in a direction opposite to a third direction D3 through the first interlayers ILDa and the first sacrificial layers SLa, and filling the first vertical channel holes CH1 with a channel sacrificial layer (not shown). The formation of the second mold structure MS2 may include sequentially stacking second interlayers ILDb and second sacrificial layers SLb, and forming second vertical channel holes CH2 that penetrate in a direction opposite to the third direction D3 through the second interlayers ILDb and the second sacrificial layers SLb. The second vertical channel holes CH2 may vertically overlap the first vertical channel holes CH1, and the formation of the second vertical channel holes CH2 may expose the channel sacrificial layer that fills the first vertical channel holes CH1. Afterwards, the exposed channel sacrificial layer may be removed, and the first and second vertical channel holes CH1 and CH2 may expose lateral surfaces of the first mold structure MS1 and the second mold structure MS2, respectively.

Before the formation of the first vertical channel holes CH1 and the second vertical channel holes CH2, a trimming process may be performed on the mold structure MS on the contact region CCR. The trimming process may include forming a mask pattern that partially covers a top surface of the mold structure MS on the cell array region CAR and the contact region CCR, using the mask pattern to pattern the mold structure MS, reducing an area of the mask pattern, and using the reduced mask pattern to pattern the mold structure MS. The reducing the area of the mask pattern and the using the reduced mask pattern to pattern the mold structure MS may be performed alternately and repeatedly. The trimming process may cause the mold structure MS to have a stepwise structure.

The first and second sacrificial layers SLa and SLb may be formed of a material that can be etched having an etch selectivity with respect to the first and second interlayers ILDa and ILDb. For example, the first and second sacrificial layers SLa and SLb may be formed of silicon nitride, and the first and second interlayers ILDa and ILDb may be formed of silicon oxide. The first and second sacrificial layers SLa and SLb may have substantially the same thickness, and the first and second interlayers ILDa and ILDb may have their thicknesses that are changed at certain portions thereof.

Thereafter, vertical channel structures VS may be formed to fill the first and second vertical channel holes CH1 and CH2. The formation of each of the vertical channel structures VS may include forming a data storage pattern DSP and a vertical semiconductor pattern VSP that conformally cover inner lateral surfaces of the first and second vertical channel holes CH1 and CH2, forming a buried dielectric pattern VI in a space surrounded by the vertical semiconductor pattern VSP, and forming a conductive pad PAD in a space surrounded by the buried dielectric pattern VI and the data storage pattern DSP.

After the formation of the stepwise structure, one or more sacrificial pads RPAD may be formed on each stair of the stepwise structure. The sacrificial pads RPAD may be formed on ends of the first and second sacrificial layers SLa and SLb. The sacrificial pads RPAD may be formed of a material having the same etch properties as those of the first and second sacrificial layers SLa and SLb. For example, the sacrificial pads RPAD may include silicon nitride.

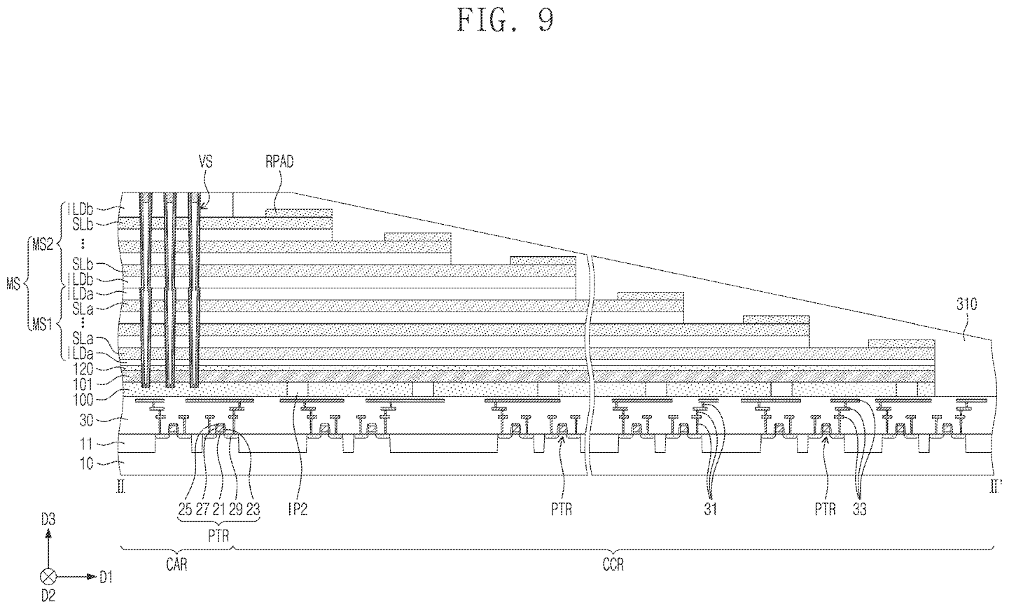

Referring to FIG. 9, a first dielectric layer 310 is formed to cover the stepwise structure of the mold structure MS on the contact region CCR. The first dielectric layer 310 may have a top surface that becomes lower in a first direction D1 along the stepwise structure of the mold structure MS.

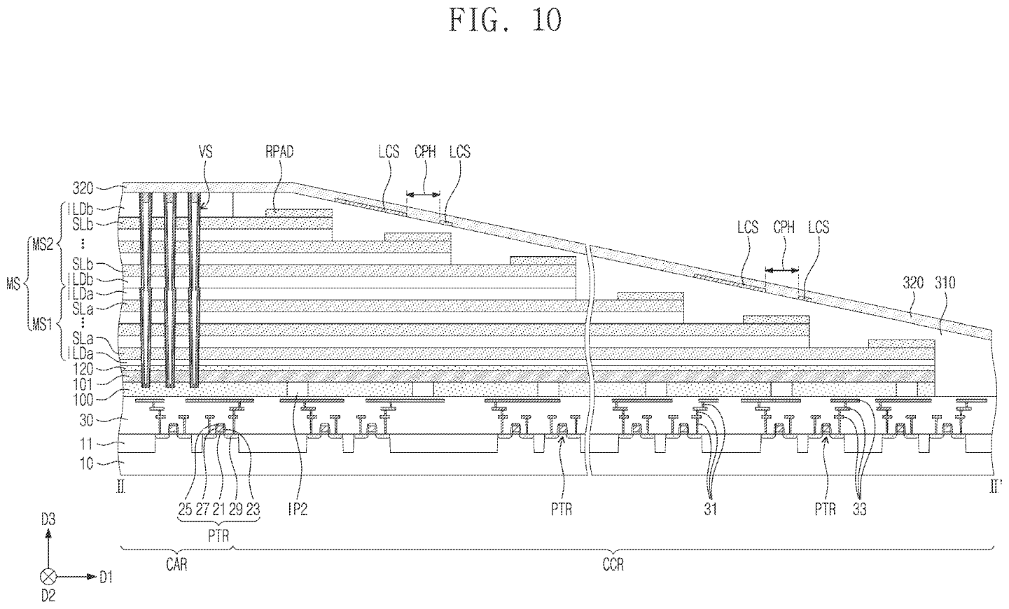

Referring to FIG. 10, a lower sacrificial layer LCS is formed on the first dielectric layer 310 on an upper portion of an area having the stepwise structure of the mold structure MS. A contact separation hole CPH may be formed in the lower sacrificial layer LCS. The contact separation hole CPH may be formed on a position where a cell contact plug CCP is formed as discussed below. The contact separation hole CPH may vertically overlap the sacrificial pad RPAD, and when viewed in plan, may be formed on substantially the same position as that of the sacrificial pad RPAD. A plurality of lower sacrificial layers LCS may be formed on the first dielectric layer 310, and each lower sacrificial layer LCS may include the contact separation hole CPH. An first interlayer dielectric layer 320 may be formed to cover the first dielectric layer 310 and the lower sacrificial layer LCS. The first interlayer dielectric layer 320 may fill the contact separation hole CPH of the lower sacrificial layer LCS, and may have a top surface that becomes lower in the first direction D1 along the stepwise structure of the mold structure MS. The first interlayer dielectric layer 320 may cover a top surface of the vertical channel structure VS on the cell array region CAR.

Referring to FIGS. 11A and 11B, an upper sacrificial layer UCS is formed on the first interlayer dielectric layer 320 on an upper portion of an area having the stepwise structure of the mold structure MS. A contact separation hole CPH may be formed in the upper sacrificial layer UCS. The contact separation hole CPH of the upper sacrificial layer UCS may vertically overlap the contact separation hole CPH of the lower sacrificial layer LCS, and when viewed in plan, may be formed at substantially the same position as that of the contact separation hole CPH of the lower sacrificial layer LCS. A plurality of upper sacrificial layers UCS may be formed on the first interlayer dielectric layer 320, and each upper sacrificial layer UCS may include the contact separation hole CPH therein. A second dielectric layer 330 may be formed to cover the first interlayer dielectric layer 320 and the upper sacrificial layer UCS. The second dielectric layer 330 may fill the contact separation hole CPH of the upper sacrificial layer UCS, and may have a top surface that becomes lower in the first direction D1 along the stepwise structure of the mold structure MS.

The lower sacrificial layer LCS and the upper sacrificial layer UCS may be formed of a material having the same etch properties as that of the first and second sacrificial layers SLa and SLb. For example, the lower and upper sacrificial layers LCS and UCS may include silicon nitride. Different from that shown, the lower and upper sacrificial layers LCS and UCS may have substantially the same thickness as that of an area where are formed the first and second sacrificial layers SLa and SLb and the sacrificial pad RPAD.

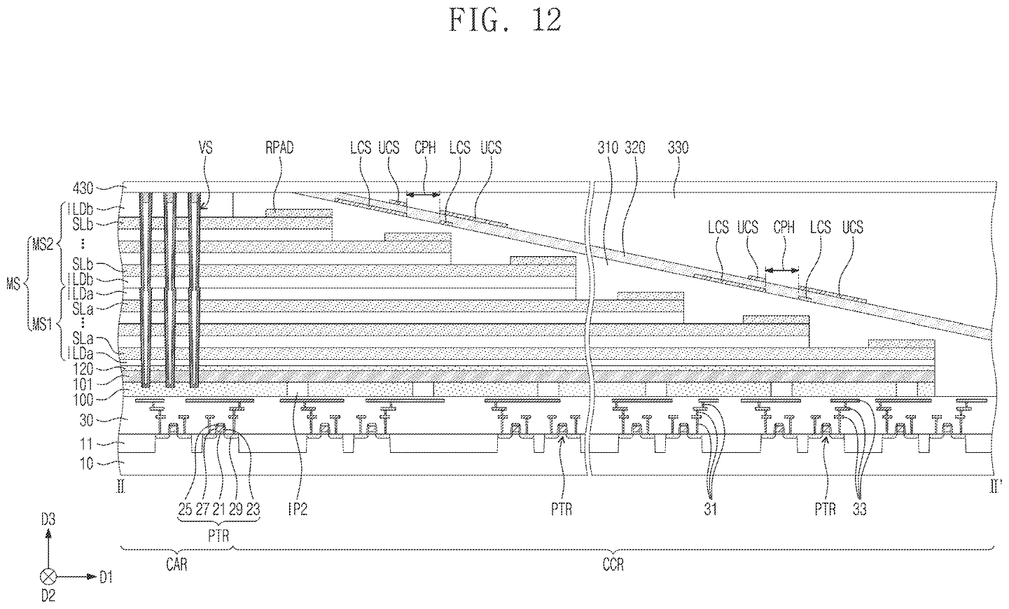

Referring to FIG. 12, a planarization process is performed on the first interlayer dielectric layer 320 and the second dielectric layer 330, and then a fourth dielectric layer 430 may be formed. The planarization process may include, for example, a chemical mechanical polishing (CMP) process or an etch-back process. Therefore, an uppermost second interlayer ILDb, the vertical channel structure VS, and the second dielectric layer 330 may have their top surfaces that are substantially coplanar with each other.

The first dielectric layer 310, the first interlayer dielectric layer 320, the second dielectric layer 330, and the fourth dielectric layer 430 may be formed by using a layer formation technique, such as chemical vapor deposition (CVD) or physical vapor deposition (PVD).

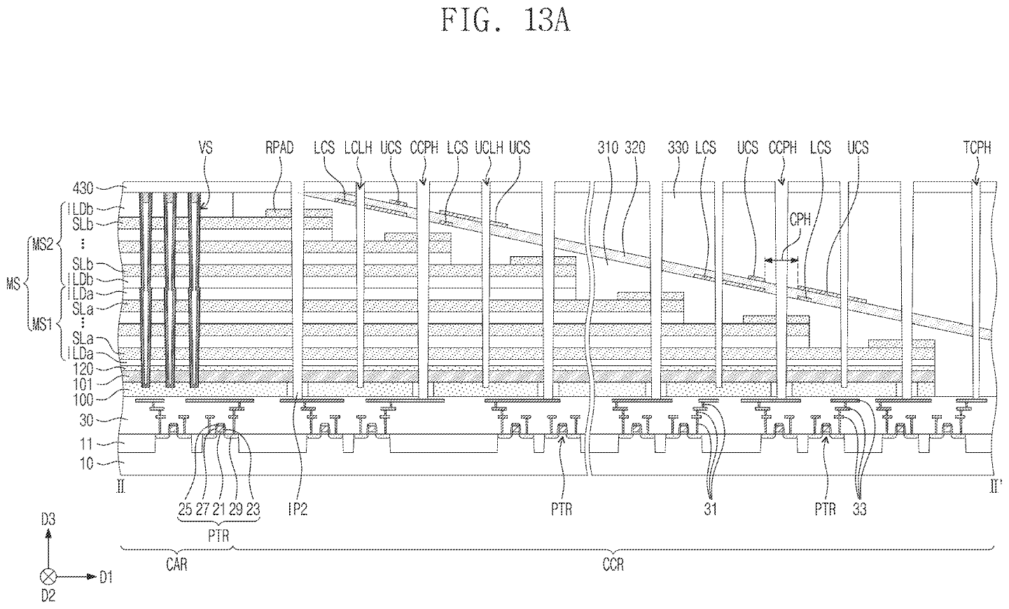

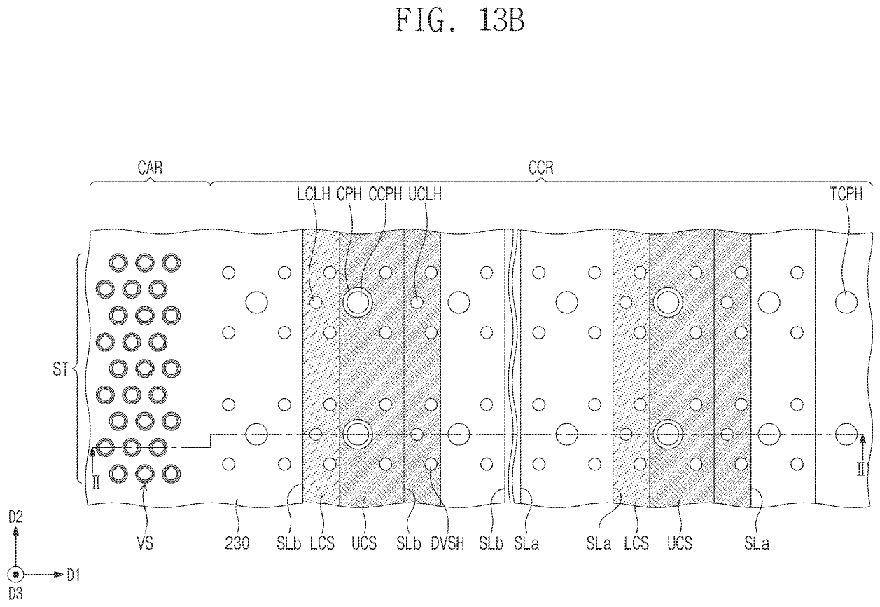

Referring to FIGS. 13A and 13B, on the contact region CCR, contact plug holes CCPH are formed to penetrate the fourth dielectric layer 430, the second dielectric layer 330, the first interlayer dielectric layer 320, the sacrificial pad RPAD, the mold structure MS, the first dielectric layer 310, and at least a portion of the lower dielectric layer 30. Some of the contact plug holes CCPH may penetrate the contact separation holes CPH of the lower and upper sacrificial layers LCS and UCS. A diameter in the first direction D1 of the contact plug hole CCPH may be less than a diameter in the first direction D1 of the contact separation hole CPH. The contact plug holes CCPH may expose a portion of a sidewall of the mold structure MS.

On the contact region CCR, a lower conductive hole LCLH may be formed to penetrate the fourth dielectric layer 430, the second dielectric layer 330, the first interlayer dielectric layer 320, the lower sacrificial layer LCS, the first dielectric layer 310, and the mold structure MS. In addition, a upper conductive hole UCLH may be formed to penetrate the fourth dielectric layer 430, the second dielectric layer 330, the upper sacrificial layer UCS, the first interlayer dielectric layer 320, the first dielectric layer 310, and the mold structure MS. The lower and upper conductive holes LCLH and UCLH may be simultaneously formed with a dummy vertical channel hole (not shown). The lower and upper conductive holes LCLH and UCLH may expose a portion of a partial sidewall of the mold structure MS.

On the contact region CCR, a peripheral contact hole TCPH may be formed to penetrate the fourth dielectric layer 430, the second dielectric layer 330, the first interlayer dielectric layer 320, the first dielectric layer 310, and at least a portion of the lower dielectric layer 30.

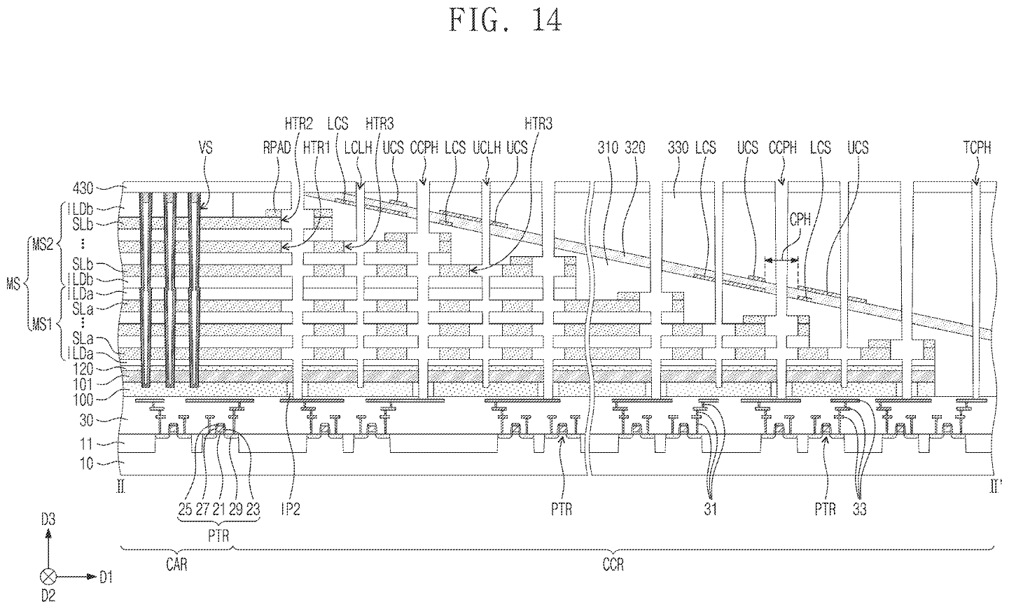

Referring to FIG. 14, the portion of the sidewall of the mold structure MS exposed by the contact plug hole CCPH is removed to form a first horizontal through recess HTR1 and a second horizontal through recess HTR2. For example, the sacrificial pad RPAD may be partially recessed, and the first and second sacrificial layers SLa and SLb may also be partially recessed. The first horizontal through recess HTR1 may be a horizontal recess that is formed on an area where the sacrificial pad RPAD is not provided. The second horizontal through recess HTR2 may be a horizontal recess that is formed on an area where the sacrificial pad RPAD and one of the first and second sacrificial layers SLa and SLb are simultaneously removed on a zone where the sacrificial pad RPAD is provided. The portion of the sidewall of the mold structure MS exposed by the lower and upper conductive holes LCLH and UCLH may be removed to form a third horizontal through recess HTR3. For example, the first and second sacrificial layers SLa and SLb may be partially removed through the exposed sidewall of the mold structure MS, and thus a recessed portion may be formed.

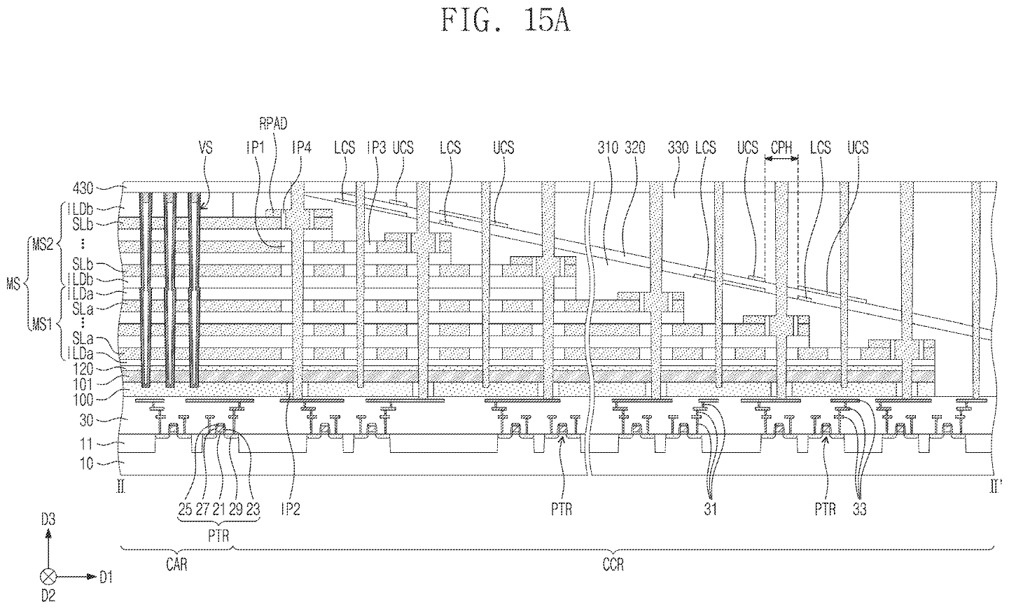

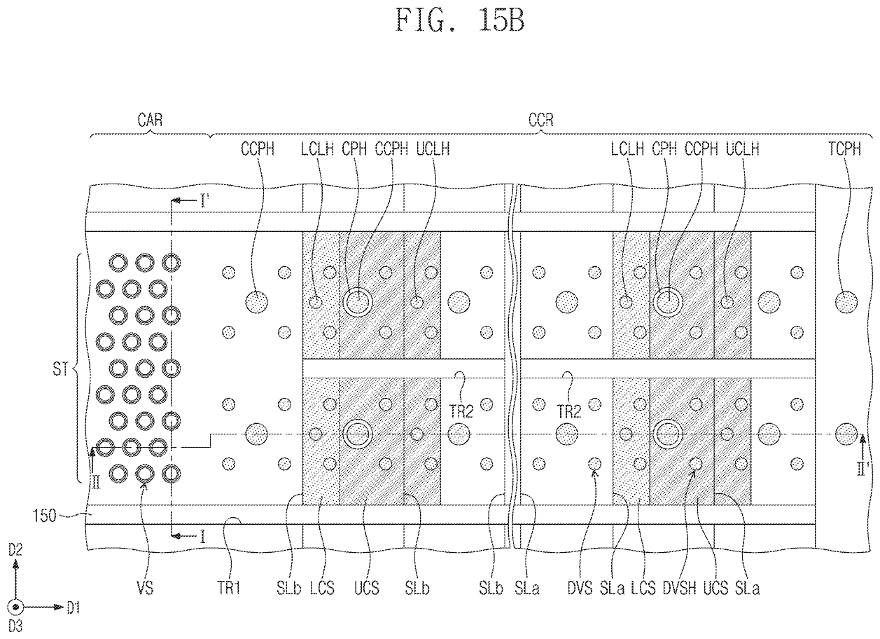

Referring to FIGS. 15A and 15B, there is formed a first dielectric pattern IP1, a third dielectric pattern IP3, and a fourth dielectric pattern IP4. For example, a sidewall dielectric layer (not shown) may be deposited to conformally cover inner walls of the first, second, and third horizontal through recesses HTR1, HTR2, and HTR3, an inner wall of the contact plug hole CCPH, and inner walls of the lower and upper conductive holes LCLH and UCLH, and the sidewall dielectric layer on sidewalls of the contact plug hole CCPH and the lower and upper conductive holes LCLH and UCLH may be removed to form the first dielectric pattern IP1, the third dielectric pattern IP3, and the fourth dielectric pattern IP4. The sidewall dielectric layer may include oxide, such as silicon oxide.

The first dielectric pattern IP1 may fill the first horizontal through recess HTR1. The third dielectric pattern IP3 may fill the third horizontal through recess HTR3. The fourth dielectric pattern IP4 may not fill at least a portion of the second horizontal through recess HTR2. As the second horizontal through recess HTR2 includes not only partially removed portions of the first and second sacrificial layers SLa and SLb, but also a partially removed portion of the sacrificial pad RPAD, the second horizontal through recess HTR2 may have a width in the third direction D3 greater than a width in the third direction D3 of each of the first and third horizontal through recesses HTR1 and HTR3, with the result that, when the sidewall dielectric layer is deposited, the second horizontal through recess HTR2 may be relatively less filled with the sidewall dielectric layer.

A sacrificial layer may be formed to fill the contact plug hole CCPH, the lower and upper conductive holes LCLH and UCLH, the dummy vertical channel hole, and the peripheral contact hole TCPH. The sacrificial layer may fill an unoccupied portion of the second horizontal through recess HTR2 in which the fourth dielectric pattern IP4 is formed. The sacrificial layer may include at least one selected from a silicon oxide layer, a silicon nitride layer, a silicon oxynitride layer, a silicon carbide layer, and a silicon-germanium layer, but the present inventive concepts are not limited thereto.

After the filling of the sacrificial layer, first and second trenches TR1 and TR2 may be formed to run in the first direction D1 across the mold structure MS. The formation of the first and second trenches TR1 and TR2 may include anisotropically etching the mold structure MS. The first trench TR1 may extend from the cell array region CAR toward the contact region CCR. The second trench TR2 may be provided on the contact region CCR. The first and second trenches TR1 and TR2 may expose a sidewall of the mold structure MS. Therefore, the first and second trenches TR1 and TR2 may expose sidewalls of the first and second sacrificial layers SLa and SLb, sidewalls of the lower and upper sacrificial layers LCS and UCS, and sidewalls of the sacrificial pads RPAD. The first and second trenches TR1 and TR2 may also outwardly expose the lower sacrificial layer 101.

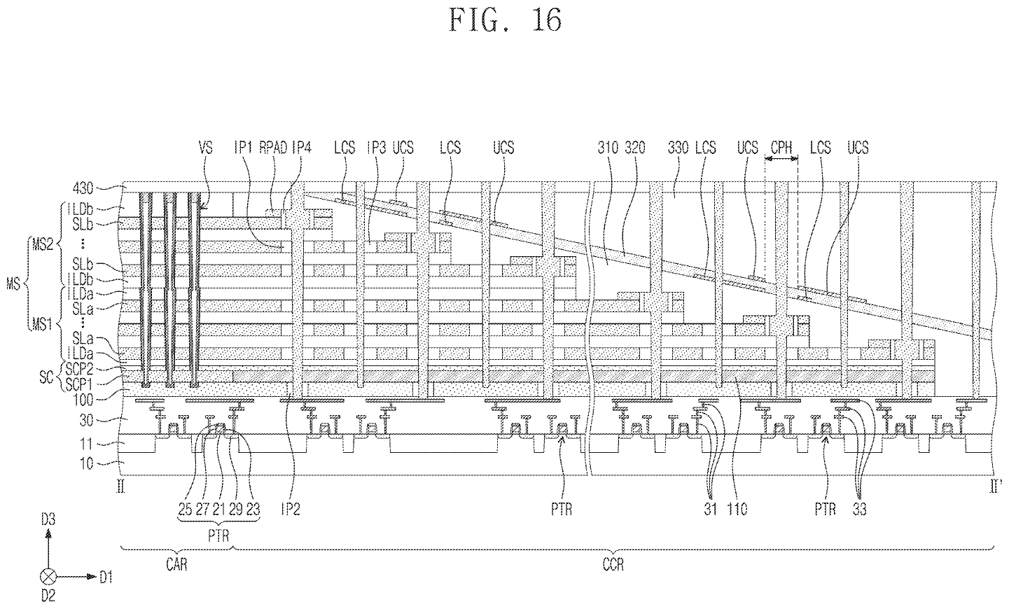

Referring to FIG. 16, on the cell array region CAR, the lower sacrificial layer 101 is replaced with a first source conductive pattern SCP1. The formation of the first source conductive pattern SCP1 may include performing an isotropic etching process on the exposed lower sacrificial layer 101. In the isotropic etching process, a portion of the data storage pattern DSP may be isotropically etched to expose a portion of the vertical semiconductor pattern VSP. An impurity-doped polycrystalline silicon layer may be deposited to form the first source conductive pattern SCP1. In this stage, a remaining lower semiconductor layer 120 may be called a second source conductive pattern SCP2, and the first source conductive pattern SCP1 and the second source conductive pattern SCP2 may constitute a source structure SC. The source structure SC may be formed between the second substrate 100 and the mold structure MS.

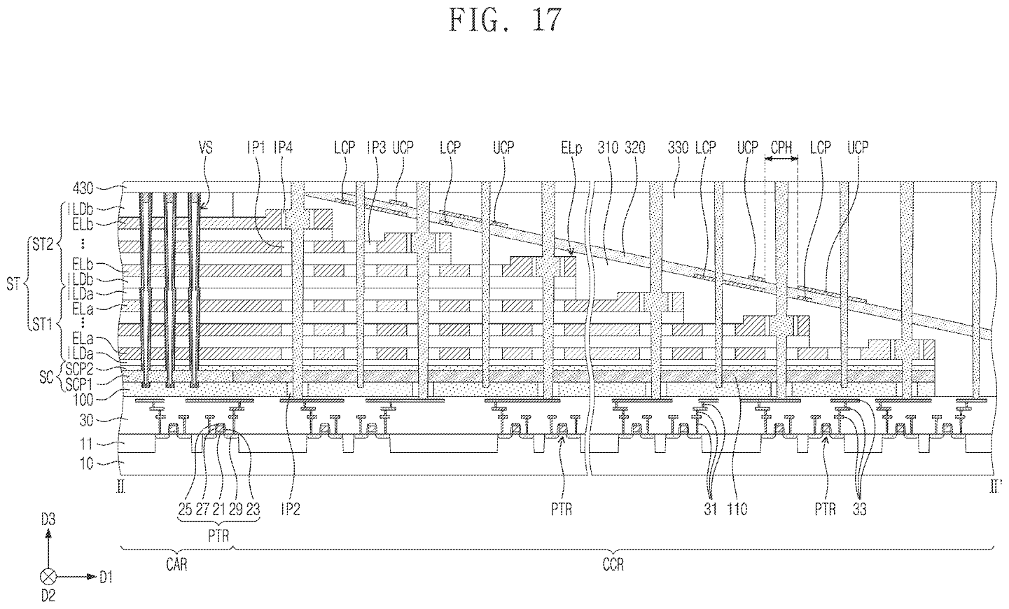

Referring to FIG. 17, the first and second sacrificial layers SLa and SLb and the sacrificial pads RPAD are replaced with first and second gate electrodes ELa and ELb. The formation of the first and second gate electrodes ELa and ELb may include performing an isotropic etching process on the sacrificial pads RPAD and the first and second sacrificial layers SLa and SLb exposed by the first and second trenches TR1 and TR2, and depositing the first and second gate electrodes ELa and ELb in locations where the sacrificial pads RPAD and the first and second sacrificial layers SLa and SLb are removed. Thus, a first stack structure ST1 may be formed which is constituted by the first gate electrodes ELa and the first interlayers ILDa, and a second stack structure ST2 may be formed which is constituted by the second gate electrodes ELb and the second interlayers ILDb. The first and second stack structures ST1 and ST2 may constitute a stack structure ST. When the first and second gate electrodes ELa and ELb are formed, pad parts ELp of the first and second gate electrodes ELa and ELb may be formed in areas where the sacrificial pads RPAD are removed.

The lower and upper sacrificial layers LCS and UCS may be replaced with lower and upper electrode plates LCP and UCP. The formation of the lower and upper electrode plates LCP and UCP may include performing an isotropic etching process on the lower and upper sacrificial layers LCS and UCS exposed by the first and second trenches TR1 and TR2, and depositing the lower and upper electrode plates LCP and UCP in locations where the lower and upper sacrificial layers LCS and UCS are removed.

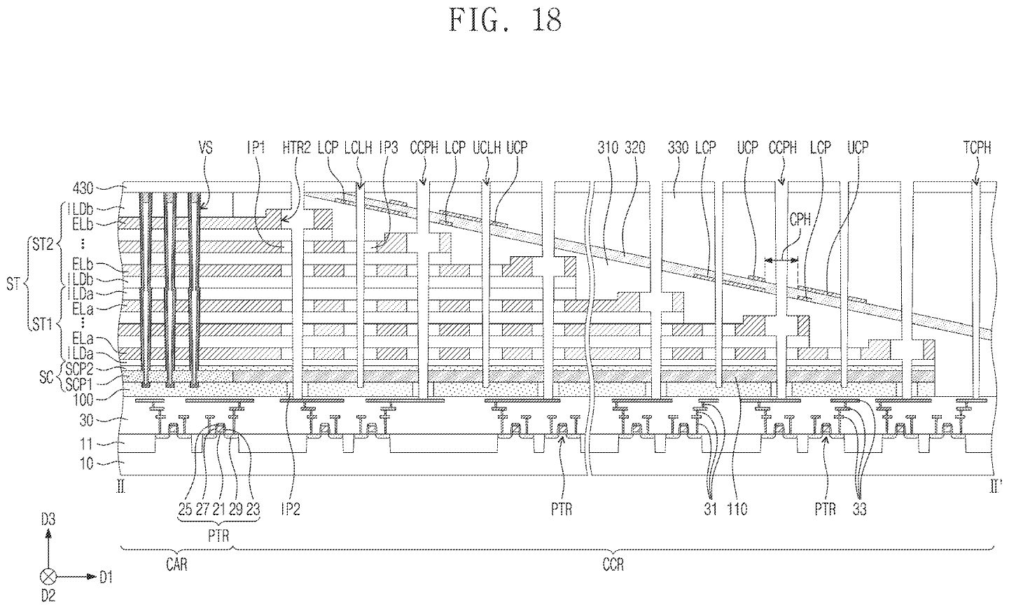

Referring to FIG. 18, the sacrificial layers are removed to outwardly expose the contact plug hole CCPH, the lower and upper conductive holes LCLH and UCLH, and the peripheral contact hole TCPH. The removal of the sacrificial layers may expose sidewalls of the first, third, and fourth dielectric patterns IP1, IP3, and IP4. A removal process may be performed on the first, third, and fourth dielectric patterns IP1, IP3, and IP4, and the removal process may completely remove the fourth dielectric pattern IP4 having a relatively small thickness. Thus, in the second horizontal through recess HTR2, the first and second gate electrodes ELa and ELb may be outwardly exposed. It may not be expected to completely remove the first and third dielectric patterns IP1 and IP3 each having a relatively large thickness.

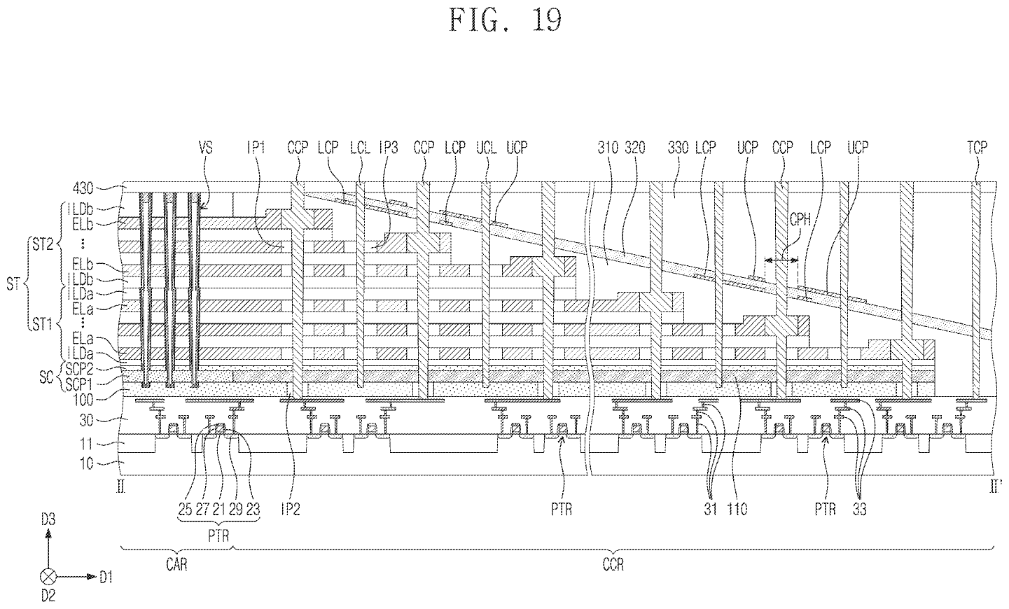

Referring to FIG. 19, there is formed a cell contact plug CCP, lower and upper conductive lines LCL and UCL, and a peripheral contact plug TCP. The cell contact plugs CCP may further fill the second horizontal through recesses HTR2. The cell contact plugs CCP may be electrically connected to corresponding gate electrodes ELa and ELb, and may be electrically separated through the first dielectric pattern IP1 from other gate electrodes ELa and ELb. The contact separation hole CPH may separate the cell contact plugs CCP from the lower and upper electrode plates LCP and UCP. For example, the contact separation hole CPH may allow the first interlayer dielectric layer 320 to be interposed between the lower electrode plate LCP and the cell contact plug CCP, and may allow the second dielectric layer 330 to be interposed between the upper electrode plate UCP and the cell contact plug CCP. The lower conductive line LCL may be electrically connected to a corresponding lower electrode plate LCP, and may be separated through the third dielectric pattern IP3 from the gate electrodes ELa and ELb. The upper conductive line UCL may be electrically connected to a corresponding upper electrode plate UCP, and may be separated through the third dielectric pattern IP3 from the gate electrodes ELa and ELb.

Referring back to FIGS. 5, 6A, and 6B, bit-line contact plugs BLCP are formed in the fourth dielectric layer 430, and bit lines BL and first and second conductive lines CL1 and CL2 may be formed on the fourth dielectric layer 430.

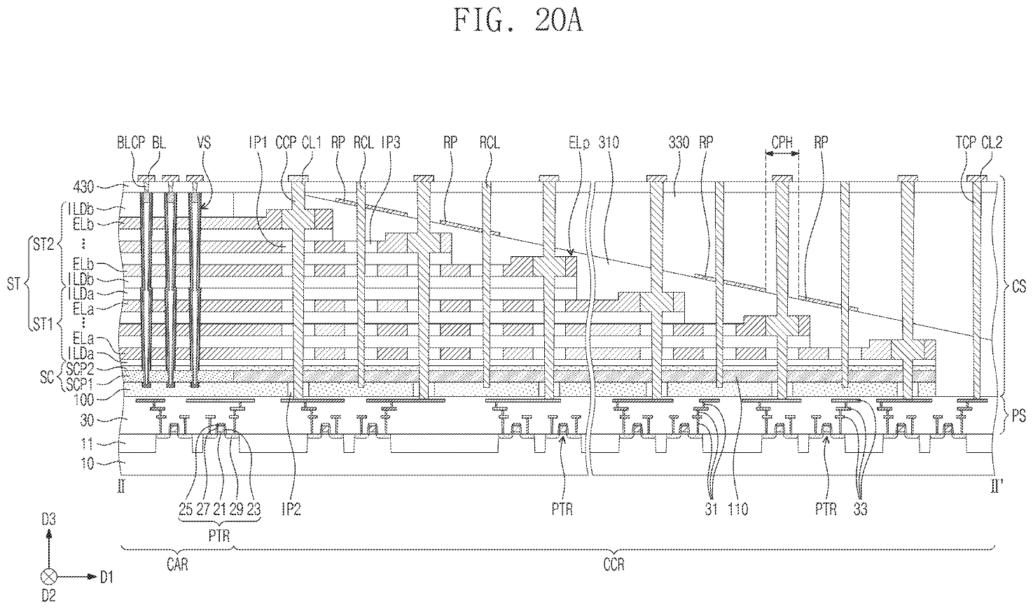

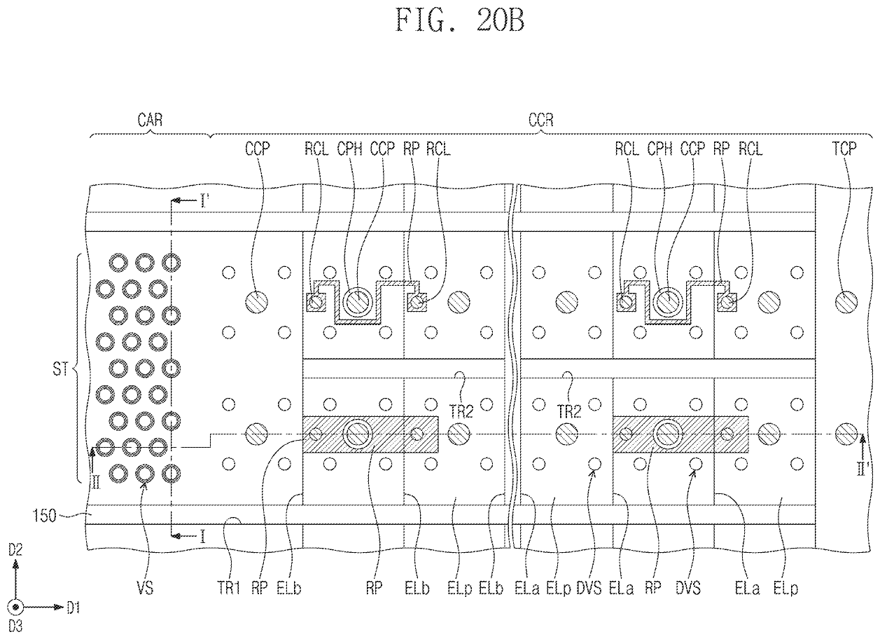

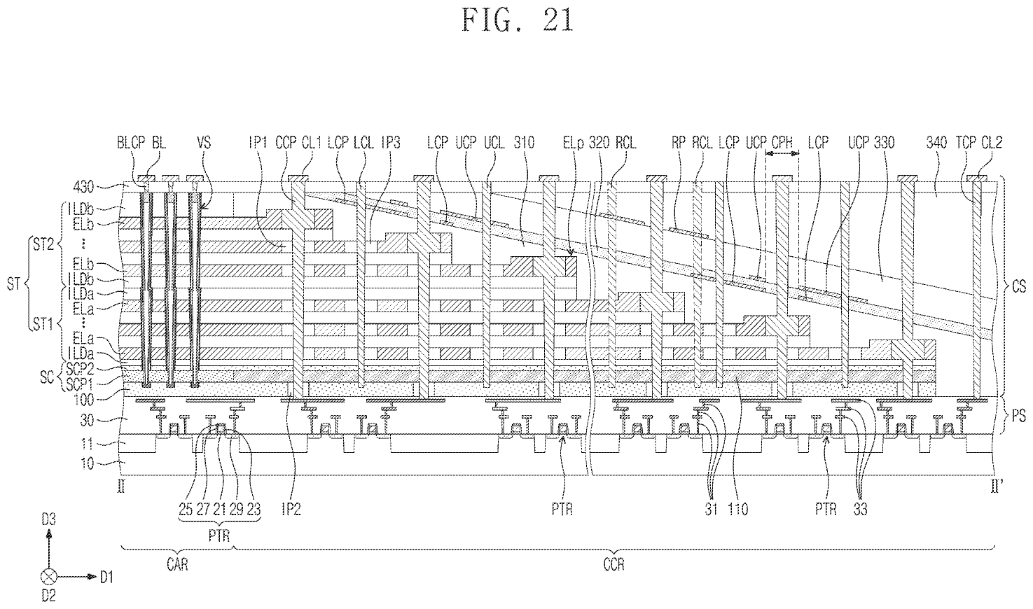

FIGS. 20A and 21 illustrate cross-sectional views showing a three-dimensional semiconductor memory device according to some implementations of the present inventive concepts. FIG. 20B illustrates a plan view showing a three-dimensional semiconductor memory device according to some implementations of the present inventive concepts. The following will omit a repetitive description and describe a three-dimensional semiconductor memory device according to some implementations of the present inventive concepts.

Referring to FIGS. 20A and 20B, a first dielectric layer 310 and a second dielectric layer 330 are provided to cover the pad part ELp of the stack structure ST. A plurality of interlayer resistive plates RP may be disposed on an upper portion of the first dielectric layer 310, and each of the plurality of interlayer resistive plates RP may vertically overlap the pad part ELp of the stack structure ST. The interlayer resistive plate RP may have a contact separation hole CPH therein, and the contact separation hole CPH may electrically separate the interlayer resistive plate RP from the cell contact plug CCP. Resistance conductive lines RCL may be provided to penetrate the fourth dielectric layer 430, the second dielectric layer 330, the interlayer resistive plates RP, and the first dielectric layer 310. The resistance conductive lines RCL may be electrically connected to the interlayer resistive plates RP, and the third dielectric pattern IP3 may electrically separate the resistance conductive lines RCL from the gate electrodes ELa and ELb. When viewed in plan, the interlayer resistive plate RP may have a zigzag shape for an increase in length and resistance. As the interlayer resistive plate RP is disposed on the pad part ELp of the stack structure ST, it may be possible to utilize a space formed of only ordinary dielectric layers and as a result to reduce a size of the three-dimensional semiconductor memory device.

Referring to FIG. 21, a plurality of interlayer capacitors ILC are disposed between the first dielectric layer 310 and the second dielectric layer 330, and each of the plurality of interlayer capacitors ILC vertically overlaps the pad part ELp of the stack structure ST. A plurality of interlayer resistive plates RP may be disposed on the second dielectric layer 330. An upper dielectric layer 340 may be provided to cover the second dielectric layer 330 and the interlayer resistive plates RP. As the interlayer resistive plates RP and the interlayer capacitors ILC are disposed together on the pad part ELp of the stack structure ST, it may be possible to utilize a space formed of only ordinary dielectric layers and as a result to reduce a size of the three-dimensional semiconductor memory device.

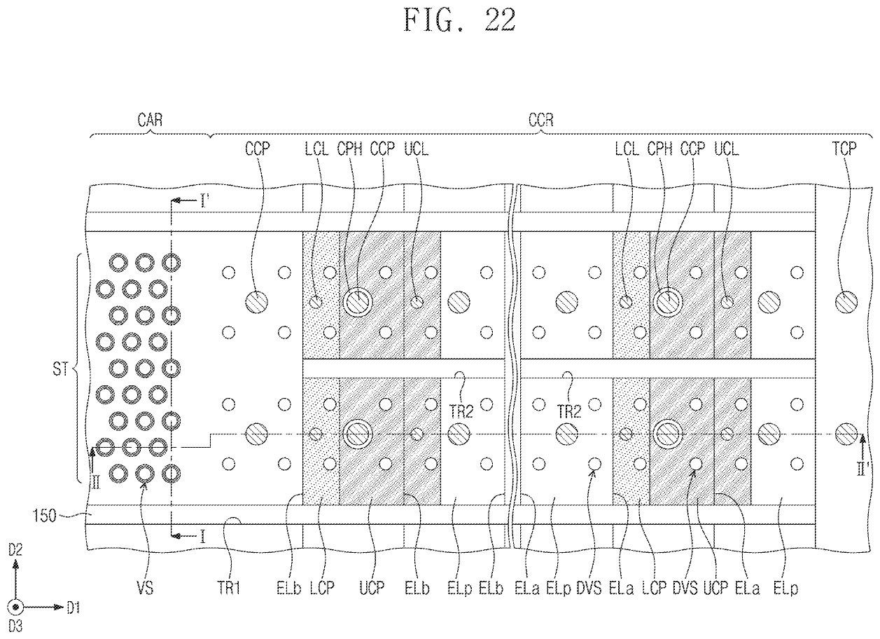

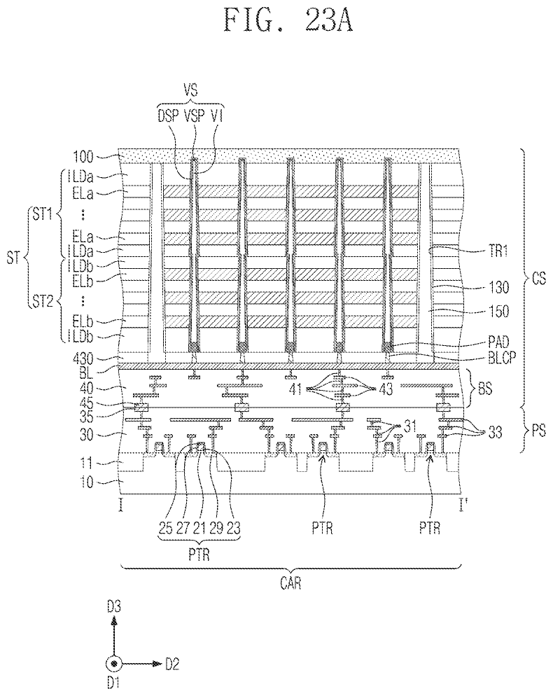

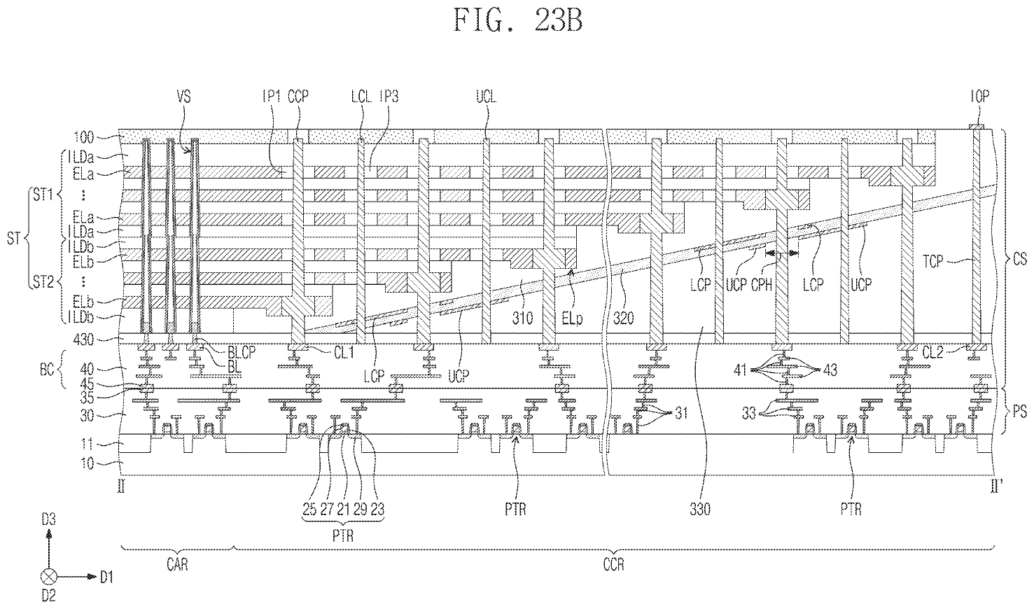

FIG. 22 illustrates a plan view showing a three-dimensional semiconductor memory device according to some implementations of the present inventive concepts. FIGS. 23A and 23B illustrate cross-sectional views respectively taken along lines I-I′ and II-II′ of FIG. 22, showing a three-dimensional semiconductor memory device according to some implementations of the present inventive concepts. For convenience of description, omission will be made to avoid a repetitive explanation of the same components discussed with reference to FIGS. 5, 6A, and 6B, and a difference thereof will be described in detail.

Referring to FIGS. 22, 23A, and 23B, a first substrate 10 is provided thereon with a peripheral circuit structure PS including peripheral circuit transistors PTR, peripheral contact plugs 31, peripheral circuit lines 33 electrically connected through the peripheral contact plugs 31 to the peripheral circuit transistors PTR, first bonding pads 35 electrically connected to the peripheral circuit lines 33, and a lower dielectric layer 30 that surrounds the peripheral circuit transistors PTR, the peripheral contact plugs 31, the peripheral circuit lines 33, and the first bonding pads 35. The lower dielectric layer 30 may not cover top surfaces of the first bonding pads 35. The lower dielectric layer 30 may have a top surface substantially coplanar with those of the first bonding pads 35.

The peripheral circuit structure PS may be provided thereon with a cell array structure CS including a bonding structure BS, a stack structure ST, and a second substrate 100. The second substrate 100 may be provided on the stack structure ST. The stack structure ST may be provided between the second substrate 100 and the peripheral circuit structure PS. The bonding structure BS may be provided between the peripheral circuit structure PS and the cell array structure CS.

The bonding structure BS may include second bonding pads 45 on the lower dielectric layer 30 and in contact with the first bonding pads 35 of the peripheral circuit structure PS, connection contact plugs 41, connection circuit lines 43 electrically connected through the connection contact plugs 41 to the second bonding pads 45, and a fifth dielectric layer 40 that surrounds the second bonding pads 45, the connection contact plugs 41, and the connection circuit lines 43. The fifth dielectric layer 40 may include a plurality of stacked dielectric layers. The fifth dielectric layer 40 may include, for example, one or more of silicon oxide, silicon nitride, silicon oxynitride, and low-k dielectric materials. The connection contact plugs 41 may each have a width in a first direction D1 or a second direction D2 that decreases in a third direction D3 (or decreases with increasing distance from the first substrate 10). The connection contact plugs 41 and the connection circuit lines 43 may include a conductive material, such as metal.

The fifth dielectric layer 40 may not cover bottom surfaces of the second bonding pads 45. The fifth dielectric layer 40 may have a bottom surface substantially coplanar with those of the second bonding pads 45. The bottom surfaces of the second bonding pads 45 may be correspondingly in direct contact with the top surfaces of the first bonding pads 35. The first and second bonding pads 35 and 45 may include metal, such as copper (Cu), tungsten (W), aluminum (Al), nickel (Ni), or tin (Sn). For example, the first and second bonding pads 35 and 45 may include copper (Cu). The first bonding pad 35 and the second bonding pad 45 may constitute a single unitary shape with no interface therebetween. Although the first and second bonding pads 35 and 45 are illustrated to have their sidewalls aligned with each other, the present inventive concepts are not limited thereto, and when viewed in plan, the first and second bonding pads 35 and 45 may have their sidewalls spaced apart from each other.

The fifth dielectric layer 40 may be provided on its upper portion with bit lines BL and first and second conductive lines CL1 and CL2 in contact with the connection contact plugs 41. A fourth dielectric layer 430 may be provided on the fifth dielectric layer 40, and the fourth dielectric layer 430 may be provided thereon with the stack structure ST, the second dielectric layer 330, and the first dielectric layer 310. Interlayer capacitors ILC may be disposed between the second dielectric layer 330 and the first dielectric layer 310. The interlayer capacitors ILC may include lower and upper electrode plates LCP and UCP and lower and upper conductive lines LCL and UCL.

First gate electrodes ELa of a first stack structure ST1 and second gate electrodes ELb of a second stack structure ST2 may have their lengths in the first direction D1 that increase with increasing distance from the first substrate 10. When viewed in plan as shown in FIG. 22, the first and second gate electrodes ELa and ELb may have their sidewalls that are spaced apart at a regular interval from each other along the first direction D1. A lowermost one of the second gate electrodes ELb included in the second stack structure ST2 may have a minimum length in the first direction D1, and an uppermost one of the first gate electrodes ELa included in the first stack structure ST1 may have a maximum length in the first direction D1. Similar to the first and second gate electrodes ELa and ELb, first and second interlayers ILDa and ILDb may have their lengths in the first direction D1 that increase with increasing distance from the first substrate 10. Bit-line contact plugs BLCP, cell contact plugs CCP, a peripheral contact plug TCP, lower and upper conductive lines LCL and UCL, and vertical channel structures VS may each have a width in the first direction D1 or the second direction D2 that decreases in the third direction D3. A separation structure 150 may have a width in the second direction D2 that decreases in the third direction D3.

The first dielectric layer 310 may be provided thereon with an input/output pad IOP electrically connected through the peripheral contact plug TCP to at least one of the peripheral circuit transistors PTR included in the peripheral circuit structure PS. The input/output pad IOP may correspond to the input/output pad 1101 of FIG. 1 or one of the input/output pads 2210 of FIGS. 3 and 4.

As the cell array structure CS is bonded onto the peripheral circuit structure PS, it may be possible to increase a cell capacity per unit area of a three-dimensional semiconductor memory device according to the present inventive concepts. In addition, as the peripheral circuit structure PS and the cell array structure CS are manufactured separately and then bonded to each other, the peripheral transistors PTR may be prevented from being damaged due to various heat treatment processes, and accordingly, it may be possible to improve reliability and electrical properties of a three-dimensional semiconductor memory device. As the interlayer capacitors ILC are disposed on a dielectric layer that covers the pad part ELp of the stack structure ST, it may be possible to utilize a space formed of only ordinary dielectric layers and as a result to reduce a size of the three-dimensional semiconductor memory device.

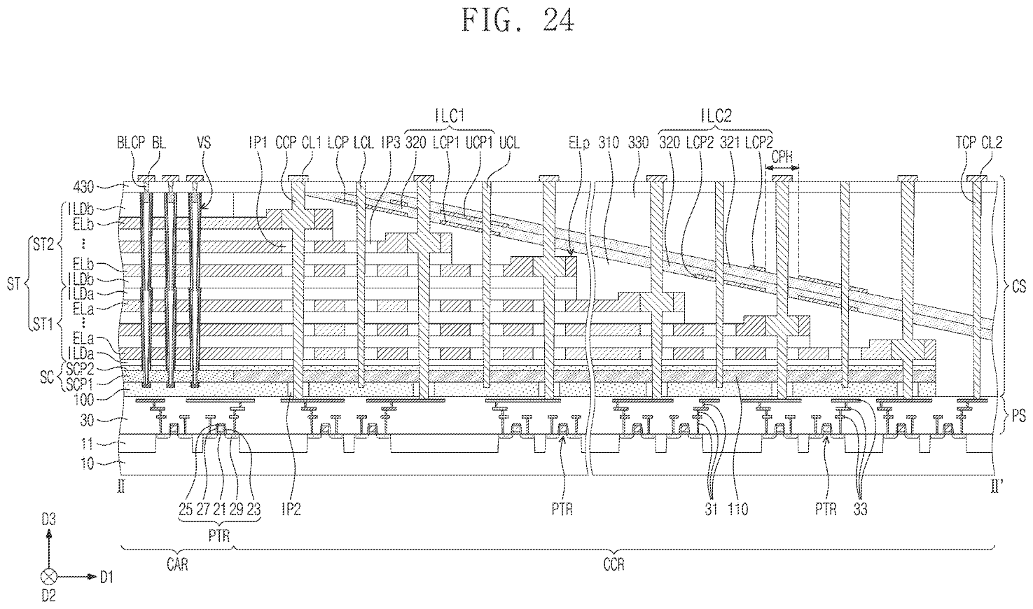

FIGS. 24 to 26 illustrate cross-sectional views showing a three-dimensional semiconductor memory device according to some implementations of the present inventive concepts. The following will omit a repetitive description and describe a three-dimensional semiconductor memory device according to some implementations of the present inventive concepts.

Referring to FIG. 24, a plurality of interlayer capacitors ILC have their interlayer dielectric layers having different thicknesses from each other. For example, a first interlayer capacitor ILC1 may include a first lower electrode plate LCP1, a first upper electrode plate UCP1, and an first interlayer dielectric layer 320. A second interlayer capacitor ILC2 may include a second lower electrode plate LCP2, a second upper electrode plate UCP2, and an first interlayer dielectric layer 320 and may further include a second interlayer dielectric layer 321. The first interlayer capacitor ILC1 may be utilized as a low-voltage capacitor, and the second interlayer capacitor ILC2 may be utilized as a high-voltage capacitor.

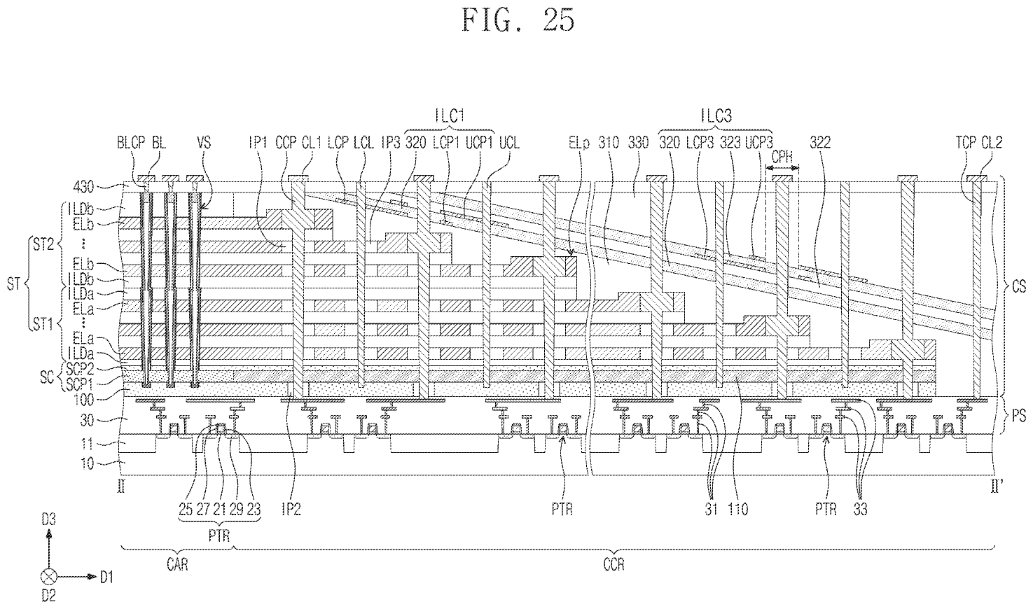

Referring to FIG. 25, on the contact region CCR, a third interlayer 322 is provided to cover the first interlayer dielectric layer 320 and the first upper electrode plate UCP1. A third lower electrode plate LCP3 may be disposed on the third interlayer 322. A third lower electrode plate LCP3 may be disposed on the third interlayer 322 on the pad part ELp. On the contact region CCR, a third interlayer dielectric layer 323 may be provided to cover the third interlayer 322 and the third lower electrode plate LCP3. A third upper electrode plate UCP3 may be disposed on the third interlayer dielectric layer 323 on the pad part ELp. For example, a plurality of interlayer capacitors ILC may be provided on different interlayer dielectric layers. For example, the first interlayer capacitor ILC1 may include the first lower electrode plate LCP1, the first upper electrode plate UCP1, and the first interlayer dielectric layer 320, and the third interlayer capacitor ILC3 may include the third lower electrode plate LCP3, the third upper electrode plate UCP3, and the third interlayer dielectric layer 323.

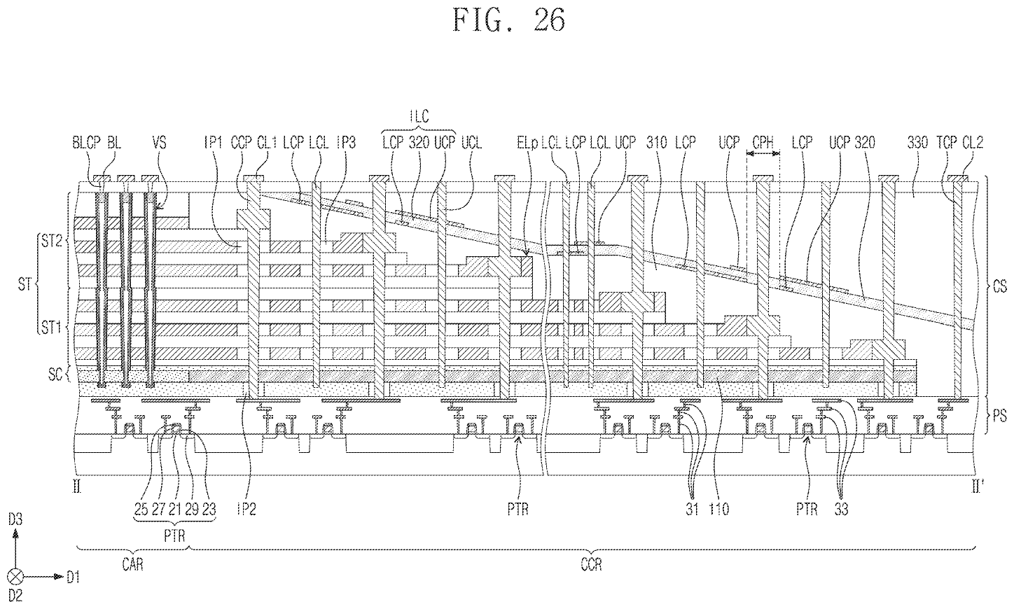

Referring to FIG. 26, the first dielectric layer 310 has a flat top surface that extends in the first direction D1 on the pad part ELp of the stack structure ST, and at least one of a plurality of interlayer capacitors ILC may be disposed on the flat top surface of the first dielectric layer 310. In addition, the first dielectric layer 310 may have a top surface that is inclined in a direction oblique to the first direction D1 on the pad part ELp of the stack structure ST, and at least one of a plurality of interlayer capacitors ILC may be disposed on the inclined top surface of the first dielectric layer 310.

A capacitor and/or a resistor may be disposed on an upper portion of a stack structure on a contact region. Therefore, as the capacitor and/or the resistor are disposed in a space formed of only dielectric layers, a three-dimensional semiconductor memory device may decrease in size.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination

Although the present invention has been described in connection with the some implementations of the present inventive concepts illustrated in the accompanying drawings, it will be understood by one of ordinary skill in the art that variations in form and detail may be made therein without departing from the spirit and essential feature of the present inventive concepts. The above disclosed implementations should thus be considered illustrative and not restrictive.

What is claimed is:

1. A three-dimensional semiconductor memory device, comprising:
a first substrate that includes a cell array region and a contact region extending from the cell array region;
a stack structure that includes interlayers and gate electrodes alternately stacked on the first substrate, wherein the stack structure includes a pad part having a stepwise structure on the contact region;
a first dielectric layer that covers the pad part of the stack structure;
a second dielectric layer on the second dielectric layer;
an interlayer capacitor between the first dielectric layer and the second dielectric layer;
a plurality of cell contact plugs that penetrate the pad part of the stack structure, the first dielectric layer, and the second dielectric layer, wherein the plurality of cell contact plugs are respectively connected to the gate electrodes; and
a lower conductive line and an upper conductive line that penetrate the pad part of the stack structure, the first dielectric layer, and the second dielectric layer, wherein the lower conductive line and the upper conductive line are electrically connected to the interlayer capacitor.

2. The device of claim 1, wherein the interlayer capacitor includes:
a lower electrode plate on the first dielectric layer;
a first interlayer dielectric layer between the first dielectric layer and the second dielectric layer, the first interlayer dielectric layer covering the lower electrode plate; and
an upper electrode plate on the first interlayer dielectric layer,
wherein the second dielectric layer covers the upper electrode plate,
wherein the first interlayer dielectric layer is between the lower electrode plate and the upper electrode plate,
wherein the lower conductive line penetrates the lower electrode plate, and
wherein the upper conductive line penetrates the upper electrode plate.

3. The device of claim 2, wherein
each of the lower electrode plate and the upper electrode plate has a contact separation hole therein,
the cell contact plug penetrates the contact separation hole,
the first interlayer dielectric layer extends into the contact separation hole between the lower electrode plate and the cell contact plug, and
the second dielectric layer extends into the contact separation hole between the upper electrode plate and the cell contact plug.

4. The device of claim 1, wherein
the interlayer capacitor is one of a plurality of interlayer capacitors between the first dielectric layer and the second dielectric layer, and
each of the plurality of interlayer capacitors vertically overlaps the pad part of the stack structure.

5. The device of claim 1, wherein the stack structure further includes a plurality of dielectric patterns between each of the gate electrodes and the lower conductive line and between each of the gate electrodes and the upper conductive line.

6. The device of claim 1, further comprising:
a peripheral circuit structure between the first substrate and the stack structure, the peripheral circuit structure including peripheral transistors;
a second substrate between the peripheral circuit structure and the stack structure;
a source structure between the stack structure and the second substrate; and
a vertical channel structure on the cell array region, the vertical channel structure filling a vertical channel hole that penetrates the stack structure and the source structure,
wherein the vertical channel structure includes a data storage pattern and a vertical semiconductor pattern that are sequentially provided on an inner sidewall of the vertical channel hole, and
wherein the source structure is in partial contact with a sidewall of the vertical semiconductor pattern of the vertical channel structure.

7. The device of claim 4, wherein the plurality of interlayer capacitors include interlayer dielectric layers different from each other.

8. The device of claim 2, further comprising a second interlayer dielectric layer between the first interlayer dielectric layer and the second dielectric layer.

9. A three-dimensional semiconductor memory device, comprising:
a first substrate that includes a cell array region and a contact region extending from the cell array region;
a stack structure that includes interlayers and gate electrodes alternately stacked on the first substrate, wherein the stack structure includes a pad part having a stepwise structure on the contact region;
a first dielectric layer that covers the pad part of the stack structure;
an interlayer resistive plate on the first dielectric layer;
a second dielectric layer that covers the first dielectric layer and the interlayer resistive plate;
a plurality of cell contact plugs that penetrate the pad part of the stack structure, the first dielectric layer, and the second dielectric layer wherein the plurality of cell contact plugs are respectively connected to the gate electrodes; and
a resistance conductive line that penetrates the pad part of the stack structure, the first dielectric layer, the interlayer resistive plate, and the second dielectric layer wherein the resistance conductive line is connected to the interlayer resistive plate.

10. The device of claim 9, wherein
the interlayer resistive plate has a contact separation hole therein,
the cell contact plug penetrates the contact separation hole, and
the second dielectric layer extends into the contact separation hole between the interlayer resistive plate and the cell contact plug.

11. The device of claim 9, wherein the stack structure further includes a plurality of dielectric patterns between the gate electrodes and the resistance conductive line.

12. The device of claim 9, wherein
the interlayer resistive plate is one of a plurality of interlayer resistive plates between the first dielectric layer and the second dielectric layer, and
each of the plurality of interlayer resistive plates vertically overlaps the pad part of the stack structure.

13. The device of claim 9, further comprising:
a peripheral circuit structure between the first substrate and the stack structure, the peripheral circuit structure including peripheral transistors;
a second substrate between the peripheral circuit structure and the stack structure;
a source structure between the stack structure and the second substrate; and
a vertical channel structure on the cell array region, the vertical channel structure filling a vertical channel hole that penetrates the stack structure and the source structure,
wherein the vertical channel structure includes a data storage pattern and a vertical semiconductor pattern that are sequentially provided on an inner sidewall of the vertical channel hole, and
wherein the source structure is in partial contact with a sidewall of the vertical semiconductor pattern of the vertical channel structure.

14. The device of claim 9, wherein the interlayer resistive plate has a zigzag shape when viewed in plan.

15. A three-dimensional semiconductor memory device, comprising:
a first substrate that includes a cell array region and a contact region extending from the cell array region;
a stack structure that includes interlayers and gate electrodes alternately stacked on the first substrate, wherein the stack structure includes a pad part having a stepwise structure on the contact region;
a first dielectric layer that covers the pad part of the stack structure;
a lower electrode plate on the first dielectric layer;
a first interlayer dielectric layer that covers the first dielectric layer and the lower electrode plate;
an upper electrode plate on the first interlayer dielectric layer;
a second dielectric layer that covers the first interlayer dielectric layer and the upper electrode plate;
an interlayer resistive plate on the second dielectric layer;
an upper dielectric layer that covers the second dielectric layer and the interlayer resistive plate;
a plurality of cell contact plugs that penetrate the pad part of the stack structure, the first dielectric layer, the first interlayer dielectric layer, the second dielectric layer, and the upper dielectric layer, wherein the plurality of cell contact plugs are respectively connected to the gate electrodes;
a lower conductive line that penetrates the pad part of the stack structure, the first dielectric layer, the first interlayer dielectric layer, the second dielectric layer, the upper dielectric layer, and the lower electrode plate;
an upper conductive line that penetrates the pad part of the stack structure, the first dielectric layer, the first interlayer dielectric layer, the second dielectric layer, the upper dielectric layer, and the upper electrode plate; and
a resistance conductive line that penetrates the pad part of the stack structure, the first dielectric layer, the first interlayer dielectric layer, the second dielectric layer, the upper dielectric layer, and the interlayer resistive plate.

16. The device of claim 15, wherein
each of the lower electrode plate, the upper electrode plate, and the interlayer resistive plate has a contact separation hole therein,
the cell contact plug penetrates the contact separation hole,
the first interlayer dielectric layer is in the contact hole between the lower electrode plate and the cell contact plug, and
the second dielectric layer is in the contact separation hole between the upper electrode plate and the cell contact plug, and
the upper dielectric layer is in the contact separation hole between the interlayer resistive plate and the cell contact plug.

17. The device of claim 15, wherein, on the pad part of the stack structure, each of the lower electrode plate, the upper electrode plate, the interlayer resistive plate, the upper conductive line, the lower conductive line, and the resistance conductive line is provided in plural.

18. An electronic system, comprising:
a first substrate that includes a cell array region and a contact region extending from the cell array region;
a three-dimensional semiconductor memory device that includes a peripheral circuit structure on the first substrate, a cell array structure on the peripheral circuit structure, a first dielectric layer that covers the cell array structure, and an input/output pad on the first dielectric layer and electrically connected to the peripheral circuit structure; and
a controller configured to electrically connect through the input/output pad with the three-dimensional semiconductor memory device and to control the three-dimensional semiconductor memory device,
wherein the cell array structure includes:
a second substrate on the peripheral circuit structure;
a stack structure that includes interlayers and gate electrodes alternately stacked on the second substrate, wherein the stack structure includes a pad part having a stepwise structure on the contact region;
the first dielectric layer that covers the pad part of the stack structure;
a second dielectric layer on the second dielectric layer;
an interlayer capacitor between the first dielectric layer and the second dielectric layer;
a plurality of cell contact plugs that penetrate the pad part of the stack structure, the first dielectric layer, and the second dielectric layer, wherein the plurality of cell contact plugs are respectively connected to the gate electrodes; and
a lower conductive line and an upper conductive line that penetrate the pad part of the stack structure, the first dielectric layer, and the second dielectric layer, wherein the lower conductive line and the upper conductive line are electrically connected to the interlayer capacitor.

19. The electronic system of claim 18, wherein the interlayer capacitor includes:
a lower electrode plate on the first dielectric layer;
a first interlayer dielectric layer between the first dielectric layer and the second dielectric layer, the first interlayer dielectric layer covering the lower electrode plate; and
an upper electrode plate on the first interlayer dielectric layer,
wherein the second dielectric layer covers the upper electrode plate,
wherein the first interlayer dielectric layer is between the lower electrode plate and the upper electrode plate, and
wherein the lower conductive line penetrates the lower electrode plate, and wherein the upper conductive line penetrates the upper electrode plate.

20. The electronic system of claim 18,
wherein the peripheral circuit structure includes:
a plurality of peripheral circuit transistors on the first substrate; and
a plurality of first bonding pads connected to the peripheral circuit transistors,
wherein the cell array structure includes:
a plurality of conductive lines connected to the cell contact plugs;
a plurality of vertical channel structures on the cell array region, the vertical channel structures filling vertical channel holes that penetrate the stack structure;
a plurality of bit lines connected to the vertical channel structures; and
a plurality of second bonding pads connected to the conductive lines and the bit lines,
wherein the plurality of first bonding pads and the plurality of first bonding pads are integrally connected into a single unitary body.
